(19) United States
(12) Patent Application Publication
(10) Pub. No.: US 2014/0295141 A1
(43) Pub. Date: Oct. 2, 2014

(54) Making the Surface of an Article Visibly Line Free

(71) Applicant: E I DU PONT DE NEMOURS AND COMPANY, Wilmington, DE (US)

(72) Inventor: Juan Carlos Figueroa, Wilmington, DE (US)

(73) Assignee: E I DU PONT DE NEMOURS AND COMPANY, Wilmington, DE (US)

(21) Appl. No.: 14/108,717

(22) Filed: Dec. 17, 2013

Related U.S. Application Data
(60) Provisional application No. 61/805,599, filed on Mar. 27, 2013.

(51) Int. Cl. C23C 14/34; C23C 14/12; C23C 14/14

(52) U.S. Cl. CPC C23C 14/34; C23C 14/14; C23C 14/12
USPC 428/157; 204/192.14; 428/447

(57) ABSTRACT

Processes that make the surface of an article comprising a semi-crystalline polymer substrate and vapor deposited with metal visibly line free and having a diffuse reflectance less than 2 percent. Articles metalized by these processes.

### FIELD OF THE INVENTION

Described herein are processes that make the surface of an article, comprising a semi-crystalline polymer substrate and vapor deposited with metal, visibly line free and having a diffuse reflectance less than 2 percent.

### OVERVIEW

Applying a metal layer to articles comprising thermoplastic polymers is known and includes wet chemical deposition, such as electroplating, and dry deposition, such as vapor deposition. Vapor deposition of a metal onto a polymeric surface involves either the vaporizing of molten metal heated by, e.g., resistance heating, plasma heating, or electron beam heating, or bombardment of a solid metal surface with ions of sufficient energy.

Vapor deposition has been used to make articles with reflective metal surfaces, such as reflectors and vehicle light bezels. To reduce a vehicle's weight and cost and to minimize rusting, its light bezels can be made of polymeric materials. However, upon exposure to very high temperatures during use, polymeric light bezels often deform or experience outgassing, both of which reduce their performance. Subjecting reflective, metal-coated polymeric surfaces to high temperatures may induce an increase in diffuse reflectance and/or a decrease in specular reflectance, which results in an increase in surface hazing and diminished performance.

The art has especially addressed the technical problem of reducing hazing in various ways:

U.S. Pat. No. 5,045,344 discloses metal deposition of vehicle headlight reflectors by mixing two metals in an arc vapor deposition process in which the first metal is low melting and the other is ceramic-forming and high temperature melting.

U.S. Pat. No. 5,169,229 discloses thin film arrays configured in a specific fashion and used as a mirror coating on high temperature engineering plastics that are subjected to high temperature cycling and do not deform.

U.S. Pat. No. 5,251,064 discloses that the addition of an ultraviolet absorber to a polymer substrate, whose surface has been vacuum-deposited with a reflective film, prevents degradation of the substrate, thereby preventing discoloration and reduced performance of the film.

U.S. Pat. No. 6,474,845 discloses a vehicle lamp made of aluminum flake and a binder with a softening point between 95° C. to 140° C., and whose reflective surface has a specular reflectance of 45-75 percent.

U.S. Pat. No. 6,488,384 discloses a dual-layer substrate, i.e., a plastic layer and a middle layer, onto which is vacuum-coated a light-reflecting metal layer, such that the middle layer prevents migration of evolved gases from the plastic and thereby prevents discoloration and reduced reflectance of the metal layer.

U.S. Pat. No. 6,629,769 discloses a light-reflecting molded article comprising polyester and onto whose surface metal was directly vapor deposited, which had a deflection temperature under load of at least 160° C.

U.S. Pat. No. 7,329,462 discloses a reflective article comprised of an amorphous thermoplastic substrate, a reflective metal layer, and a haze-prevention layer in-between, in which the amorphous thermoplastic has a heat distortion temperature of at least 140° C. and a volatile organic content of less than 1,000 parts per million.

U.S. Pat. App. Pub. No. 2003/0096122 discloses a molded article made of polyester and a non-blooming polymeric release agent or lubricant, whose surface has been vacuum deposited with metal and then subsequently deposited via plasma polymerization with polydimethylsiloxane.

U.S. Pat. App. Pub. No. 2010/0227182 discloses a metalized vehicle light bezel molded of a thermoplastic composition of polyester and sodium montanate and expected to exhibit less condensable outgassing compared to compositions with conventional lubricants.

U.S. Pat. App. Pub. No. 2010/0227183 discloses a metalized article molded of a thermoplastic, poly(trimethylene terephthalate) composition having low cyclic dimer content.

CN Pat. No. 101788127 discloses a process for metalizing materials by activating and cleaning the surface of the material to be metalized with plasma, performing vacuum aluminum plating, applying a protective film, UV-curing, and drying.

None of the above discloses a process that results in a coated surface of an article which surface is visibly line free and has a diffuse reflectance of less than 2 percent, after the article has been heated to a maximum temperature between 165° C. and 190° C. Thus, there is still a need for processes to produce articles having such surfaces.

Described herein are processes,

comprising the following steps done sequentially:
(1) vapor depositing onto a surface of an article comprising a semi-crystalline polymer composition a coating comprising aluminum;
(2) vapor depositing onto the same surface of the article an overcoat comprising hexamethyl disiloxane; to result in an article that, when heated to a maximum temperature between 165° C. and 190° C. between one hour and 4 hours, has a surface coated with an aluminum coating of thickness less than 200 nm and with an overcoat comprising hexamethyl disiloxane of thickness less than 325 nm, said surface being visibly line free and
having a diffuse reflectance equal to or less than 2%, as measured at 600 nm by a conventional reflectance method comprising ASTM C1650-07, wherein:
step (1) occurs in a vapor deposition chamber in an atmosphere of sputtering gas, and is done by the following substeps:
(a) sputter vaporizing the surface of an aluminum target at a maximum target power density ranging between 10 W/cm² and 40 W/cm² for a maximum duration of 2 minutes; and
(b) passing the article in front of the sputtered aluminum target surface for a maximum ranging between 2 and 25 passes; and
step (2) occurs in a vapor deposition chamber and is done by the following substeps:
(c) replacing the sputtering gas in the vapor deposition chamber with flowing hexamethyl disiloxane;
(d) flowing the hexamethyl disiloxane to achieve a residence time within the vapor deposition chamber ranging between 1 second and 20 seconds at a pressure ranging between 20 mTorr and 75 mTorr;
(e) sustaining a hexamethyl disiloxane discharge at a maximum power density ranging between 0.5 W/cm² and 3 W/cm² for a maximum duration ranging between 0.2 minutes and 3.3 minutes; and
(f) exposing the article to the hexamethyl disiloxane discharge for a maximum ranging between 1 and 40 times.
Also described are articles made from such processes, particularly in the form of vehicle light bezels.

### DETAILED DESCRIPTION

### Definitions

As used herein, the terms “a”, “an” refers to one, more than one and at least one and therefore does not necessarily limit its referent noun to the singular.

As used herein, the terms “comprises,” “comprising,” “includes,” “including,” “has,” “having”, “consisting essentially of”, and “consisting of” or any other variation of these, may refer either to a non-exclusive inclusion or to an exclusive inclusion.

When these terms refer to a non-exclusive inclusion, a process, method, article, or apparatus that comprises a list of elements is not limited to the listed elements but may include other elements not expressly listed or which may be inherent. Further, unless expressly stated to the contrary, “or” refers to an inclusive, not an exclusive, or. For example, a condition A or B is satisfied by any one of the following: A is true (or present) and B is false (or not present), A is false (or not present) and B is true (or present), and both A and B are true (or present).

When these terms refer to a more exclusive inclusion, these terms limit the scope of a claim to those recited materials or steps that materially affect the novel elements of the recited invention.

When these terms refer to a wholly exclusive inclusion, these terms exclude any element, step or component not expressly recited in the claim.

As used herein, the term “article” refers to an unfinished or finished item, thing, object, or an element or feature of an unfinished or finished item, thing or object. As used herein, when an article is identified as unfinished, the term “article” may refer to any item, thing, object, element, device, etc. that will be included in a finished article and/or will undergo further processing in order to become a finished article.

As used herein, when an article is identified as finished, the term “article” refers to an item, thing, object, element, device, etc. that has undergone processing to completion to thereby be suitable for a particular use/purpose.

An article may comprise one or more element(s) or subassembly(ies) that either are partially finished and awaiting further processing or assembly with other elements/subassemblies that together will comprise a finished article.

In addition, as used herein, the term “article” may refer to a system or configuration of articles. For example, articles having reflective metal surfaces as contemplated herein include, without limitation and for illustration purposes the following: a finished vehicle light bezel, a part of a finished vehicle light bezel, a molded polymeric part awaiting assembly into a finished light bezel, and a finished vehicle light bezel assembled into a larger configuration.

As used herein, the term “visibly line free surface” refers to a surface that, when observed by the unaided human eye, is without a feature having the appearance of a line, or a streak, or a row, or a stripe, or a linear contour, any of which is longer than 1 millimeter [1 mm]. A visibly line free surface may possess dots, spots, points, specks, blotches, freckling, etc. that do NOT have the appearance of a line longer than 1 mm. A visibly line free surface, as used herein, does NOT refer to a visibly defect free surface.

As used herein, the term “visibly defect free surface” contrasts with a visibly line free surface, in that a visibly defect free surface, when observed by the naked eye, does NOT have features having the appearance of spots, dots, points, specks, blotches, freckling, etc.

As used herein, the terms “vapor depositing”, “vapor deposition” refer to a method of coating an article with a material that is applied in vapor form. Upon contacting the substrate surface, the metal vapor condenses into a metal layer or coating onto the substrate. The terms “layer” and “coating” are used here interchangeably. A “vapor deposition chamber” is a space within which this method of coating takes place.

As used herein, the term “semi-crystalline polymer” refers to those polymer(s) having distinct volumetric regions where the molecular structure is crystalline and different volumetric regions where the molecular structure is amorphous.

As used herein, “the same surface of the article” refers to that article surface previously referred to and which has been previously treated or affected.

As used herein, the term “overcoat” refers to a subsequent coating applied to a surface having a previously applied coating.

As used herein, the term “to a temperature” refers to a temperature that an article has achieved as a result of exposure to heat or other energy.

As used herein, the term “at a temperature” refers to a temperature that an article has been exposed to as a result of exposure to heat or other energy.

As used herein, the terms “air treatment at designated temperature” and “air aging” are interchangeable.

As used herein, the term “specular reflectance” refers to a concept usefully described with reference to the term “specular reflection”. “Specular reflection” or “specularly reflected” refers to the mirror-like reflection of light whereupon light from a single incident direction is reflected into a single outgoing direction, with both directions making the same angle with respect to the surface. “Specular reflectance” refers to the fraction, expressed as a percent, of the incoming light intensity that is specularly reflected by a surface. Specular reflectance can be a function of the wavelength of the incident light.

As used herein, the term “diffuse reflectance” refers to a concept usefully described with reference to the term “diffuse reflection”. “Diffuse reflection” or “diffusely reflected” refers to the non-specular reflection of light whereupon light from a single incident direction is reflected into outgoing directions that do not include the specular direction. “Diffuse reflectance” refers to the fraction, expressed as a percent, of the incoming light intensity that is diffusely reflected by a surface. Diffuse reflectance can be a function of the wavelength of the incident light. In the processes described herein, diffuse reflectance is measured at 600 nanometers

As used herein, the term “sustaining a discharge” refers to causing the gas within the vapor deposition chamber to become at least partially ionized.

Three critical components are required to generate and deliver the electrical power into the vapor deposition chamber in order to sustain a discharge. These components are the power generator, the power applicator and the transmission line between them. The power applicator may be an electrode situated within the chamber (electrode-based system) or a window that is transparent to either RF or MW radiation (electrodeless system).

Thus, sustaining a discharge may be done by a power applicator that requires an electrode or by one that does not require an electrode. Those of skill in the art recognize which power applicators require electrodes and which do not.

As used herein, the term “plasma enhanced chemical vapor deposition” refers to a process that generates condensable species by using a gas discharge to activate or fragment gaseous precursors.

As used herein, the terms “target power density” or “electrode power density” or “power density” refer to the electrical power delivered to a target (or electrode) divided by the geometrical surface area of such target (or electrode). The power density of an electrodeless means for sustaining a discharge refers to the ratio between the radio frequency or microwave energy transmitted into the vapor deposition chamber through a dielectric plate and the geometrical surface area of such plate. These densities are measured in Watts/centimeters squared (W/cm²).

As used herein, the terms “sputter vaporizing” or “sputtering” refers to the ejection of atoms from a solid surface into the gas phase as a result of ion bombardment of such solid surface.

As used herein, the terms “discharge source”, “HMDSO discharge source” refer to that device which, upon applying to the device a voltage that exceeds the break down voltage for the specific gas flowed within the vapor deposition chamber, causes a gas discharge.

As used herein, the terms “surface of an aluminum target”, “sputtered aluminum target surface” refer to an aluminum target surface being subjected to ionic bombardment resulting in the formation of aluminum vapor.

As used herein, “passing the article in front of” refers to passing the article through a region comprising vaporized metal species. Typically, the article is on a rotating platform which passes or moves the article through the vaporized metal in the vacuum chamber causing the metal to contact and adhere to the surface of the article.

As used herein, the term “flowing” refers to injection of a gas into a vapor deposition chamber that is continuously evacuated by a vacuum pump.

As used herein, the term “residence time” refers to the average time spent by a gas molecule in the vapor deposition chamber.

As used herein, the term “HMDSO process base pressure” refers to the chamber pressure that is attained when the HMDSO vapor, injected at a particular flow rate, is pumped out of the chamber by a pump operating at full conductance.

As used herein, the term “HMDSO process pressure” refers to the chamber pressure during the discharging of the HMDSO vapor.

As used herein, the term “HMDSO process energy” refers to the product between the power used to sustain the HMDSO discharge and the discharge time.

As used herein, “lubricant” refers to a material that provides lubricating properties to the material to which it is added.

As used herein, the term “outgassing” refers to the release of a gas that was dissolved, trapped, frozen or absorbed in an article made of polymeric material upon continuous and/or long term exposure to temperatures close to the material's evaporation or sublimation temperature.

As used herein, the term “metalizing” refers to a step of treating, covering, coating, or impregnating a surface with metal or a metal compound.

As used herein, the term “adsorption” refers to the adhesion of atoms or molecules of gas, liquid, or dissolved solids to a surface. This surface phenomenon creates a film of the adsorbate (the molecules or atoms being accumulated) on the surface of the adsorbent, as a result of the attraction exerted on adsorbates by atoms on the surface of the adsorbent.

As used herein, the term “species” refers to atoms, molecules, molecular fragments, ions, etc. of gases and/or liquids and/or solids present in the gas phase during the HMDSO discharge process and/or in the air surrounding the vapor deposition unit.

As used herein, the term “thermal endurance” refers to a percent change in room temperature reflectance experienced by a surface exposed to a higher temperature for a given period of time.

As used herein, the term “thermal stability” of a surface refers to the ability of the surface, when exposed to widely varying temperatures, to accommodate the strain mismatch between the coating and the substrate without forming visually (human eye) observable surface features.

As used herein, the term “conventional reflectance method” refers to the method of measuring reflectance, diffuse and specular, according to ASTM C1650-7 (2007) as well as the specific method of measuring reflectance, diffuse and specular, required when using a specific, commercially available spectrophotometer.

For example, when using a spectrophotometer manufactured by Gretag Macbeth, model Color-Eye 7000A, the measurement of reflectance is done by the following, which is given in the instructions for using the device:

1. Configure instrument for diffuse reflectance mode
2. Install Small Aperture on Front face of instrument
3. Set Lens position to Small Aperture

### 4. Calibrate Instrument:

a. Place Zero Calibration Standard (Black) over Small Aperture,

b. Take measurement,

c. Remove Zero Calibration Standard (Black)

d. Place White Calibration Tile over Small Aperture

e. Take measurement,

5. Place graduated sample holder onto front face of instrument.
6. Place plaque to be measured onto graduated sample holder, aligning left edge of the plaque with 15 mm mark,
7. Take measurement
8. Repeat steps 5-6 by aligning left edge of the plaque with the 20, 25, 35, and 40 mm marks
9. Repeat steps 5-7 for all plaques to be measured,
10. Configure instrument for total reflectance mode,
11. Repeat steps 1-8

### Ranges

Any range set forth herein includes its endpoints unless expressly stated otherwise. Setting forth an amount, concentration, or other value or parameter as a range specifically discloses all ranges formed from any pair of any upper range limit and any lower range limit, regardless of whether such pairs are separately disclosed herein. The processes and articles described herein are not limited to the specific values disclosed in defining a range in the description.

### Preferred Variants

The setting forth of variants in terms of materials, methods, steps, values, ranges, etc.—whether identified as preferred variants or not—of the processes and articles described herein is specifically intended to disclose any process and article that includes ANY combination of such materials, methods, steps, values, ranges, etc. Such combinations are specifically intended to be preferred variants of the processes and articles described herein.

### ABBREVIATIONS

As used herein, “nanometer” is abbreviated as “nm”.

As used herein, “percent weight” is abbreviated as “% wt”.

As used herein, “hexamethyl disiloxane” is abbreviated as “HMDSO”.

As used herein, “aluminum” is abbreviated “Al”.

As used herein, hydrochloride is abbreviated “HCl”.

As used herein, “direct current” is abbreviated as “DC”.

As used herein, “radio frequency” is abbreviated as “RF”.

As used herein, “Plasma Enhanced Chemical Vapor Deposition” is abbreviated as “PECVD”.

Described herein are processes,

comprising the following steps done sequentially:
(1) vapor depositing onto a surface of an article comprising a semi-crystalline polymer composition a coating comprising aluminum;
(2) vapor depositing onto the same surface of the article an overcoat comprising hexamethyl disiloxane; and
to result in an article that, when heated to a maximum temperature between 165° C. and 190° C. between one hour and four hours, has a surface coated with an aluminum coating of thickness less than 200 nm and with an overcoat comprising hexamethyl disiloxane of thickness less than 325 nm, said surface being visibly line free and
having a diffuse reflectance equal to or less than 2%, as measured at 600 nm by a conventional reflectance method comprising ASTM C1650-07,
wherein:
step (1) occurs in a vapor deposition chamber in an atmosphere of sputtering gas, and is done by the following substeps:
(a) sputter vaporizing the surface of an aluminum target at a maximum target power density ranging between 10 W/cm² and 40 W/cm² for a maximum duration of 2 minutes; and
(b) passing the article in front of the sputtered aluminum target surface ranging between 2 and 25 passes; and
step (2) occurs in a vapor deposition chamber and is done by the following substeps:
(c) replacing the sputtering gas in the vapor deposition chamber with flowing hexamethyl disiloxane;
(d) flowing the hexamethyl disiloxane to achieve a residence time within the vapor deposition chamber ranging between 1 second and 20 seconds at a pressure ranging between 20 mTorr and 75 mTorr;
(e) sustaining a hexamethyl disiloxane discharge at a maximum power density ranging between 0.5 W/cm² and 3 W/cm² for a maximum duration ranging between 0.2 minutes and 3.3 minutes; and
(f) exposing the article to the hexamethyl disiloxane discharge ranging between 1 and 40 times.

Also described are articles made from these processes, particularly in the form of vehicle light bezels.

Any of the processes described herein may include any one or any combination of the following elements set forth below in this paragraph. And, to avoid ambiguity, this paragraph is intended to provide express, literal, and photographic support for any process described herein that includes any one or any combination of the following elements set forth below in this paragraph. Specifically, the processes described herein may include any one or any combination of the following elements:
may, before step (1), include a step of pre-conditioning the vapor deposition chamber, whereby the interior of the chamber retains species derived both from the most recent hexamethyl disiloxane discharge done in the chamber and from exposure of the interior of the vapor deposition chamber to ambient humidity during unloading and loading of articles; and/or
may in step (1) sputter vaporize with a target power density ranging between 10 W/cm² and 40 W/cm² or between 10 W/cm² and 30 W/cm²; and/or
may in step (1) achieve a duration of aluminum deposition onto the target surface, which ranges between 0.25 and 2 minutes or between 0.25 and 1.5 minutes;
may in step (1) expose the article in front of the sputtered aluminum target surface between 2 and 10 passes, or between 2 and 9 passes; and/or
may in step (1) use a pressure of the atmosphere in the vapor deposition chamber, which ranges from 1 mTorr and 25 mTorr, or from 1.5 mTorr and 10 mTorr; and/or
may in step (1) achieve an aluminum coating of thickness not more than 170 nm, or not more than 100 nm; and/or
may in step (2) use a pressure that ranges between 20 mTorr and 60 mTorr, or between 25 mTorr and 60 mTorr, or between 30 mTorr and 60 mTorr, or between 20 mTorr and 40 mTorr; and/or
may in step (2) sustain a power density that ranges between 0.6 W/cm² and 2.5 W/cm², or between 0.6 W/cm² and 2.2 W/cm²; and/or
may in step (2) sustain a power density for a duration ranging between 0.3 minutes and 3 minutes, or between 0.3 minutes and 2 minutes; and/or
may in step (2) achieve an overcoat comprising HMDSO of thickness ranging between 15 nm and 300 nm, or less than 300 nm, or less than 200 nm, or not less than 30 nm, or not less than 20 nm; and/or
may in step (2) expose the article to the HMDSO discharge between 2 and 37 times, or between 2 and 15 times, or between 2 and 8 times, or between 2 and 6 times, or between 1 and 6 times, and/or
may, after step (2), include a subsequent heating of the article to a maximum temperature above 190° C., or to 195° C. for at least one hour and up to 24 hours; and/or
may result in an article having a coated surface of specular reflectance equal to or greater than 80%, as measured at 600 nm by a conventional reflectance method comprising ASTM C1650-07; and/or
may result in an article in the form of a vehicle light bezel; and/or
may include in the semi-crystalline polymer composition a semi-crystalline polymer selected from the group consisting of polybutylene terephthalate, polyethylene terephthalate, or polytrimethylene terephthalate, and mixtures of these; and/or
may include in the semi-crystalline polymer composition 0 to 2 weight percent, or 0.01 to 2 weight percent, of at least one lubricant selected from the group consisting of long chain fatty acid polyol esters, salts of long chain fatty acids, hydrogenated castor oil, pentaerythritol tetramontanoate, dipentaerythritol hexastearate, sodium montanate, and mixtures of these; and/or
may include in the semi-crystalline polymer composition 0 to 2 weight percent carbon black; and/or
may include in the semi-crystalline polymer composition 0 to 15 weight percent mineral fillers selected from the group consisting of talc, barium sulfate, calcium carbonate, titanium dioxide, and mixtures of these.

### Step (1): Vapor Depositing a Metal Coating/Layer

Step (1)—vapor deposition of a metal coating, preferably aluminum, onto the surface of the article—occurs in a vapor deposition chamber in an atmosphere of sputtering gas, and is done by the following substeps:

(a) sputter vaporizing the surface of an aluminum target at a maximum target power density of 40 W/cm² and for a maximum duration of 2 minutes; and
(b) passing the article in front of the sputtered aluminum target surface for a maximum ranging between 2 and 25 passes to result in an article having an aluminum coating of thickness less than 200 nm. Preferably, the target power density ranges between 10 W/cm² and 40 W/cm², and more preferably between 10 W/cm² and 30 W/cm².

Vapor deposition of a metal coating (or layer) onto the surface of an article comprising a semi-amorphous crystalline polymer is done with a vacuum metalizer, which may be commercially available from several manufacturers, including Vergason Technologies, Inc., Van Etten, N.Y., USA; Mustang Vacuum Systems, Sarasota, Fla., USA; Leybold Optics GmbH, Switzerland; and A.P. Nonweiler, Oshkosh, Wis., USA.

The general configuration of a vacuum metalizer is: at least one vapor deposition chamber; a means for rotating the articles to be metalized within the chamber(s); at least one pumping system for maintaining a vacuum within the chamber(s); a cathode-anode array for generating vapor deposition discharges; power generators to ignite the discharges; connections for supplying gases and other materials into the chamber(s); and vacuum lines for removing gases and other materials from the chamber(s). Three critical components are required to generate and deliver the electrical power into the vapor deposition chamber. These are the power generator, the power applicator and the transmission line between them. The power applicator may be an electrode situated within the chamber (electrode-based system) or a window that is transparent to either RF or MW radiation (electrodeless system).

The following paragraphs describe the recited processes when the power applicator requires an electrode. To begin, the article whose surface is to be metalized, that is, coated with metal, is placed into a vapor deposition chamber of the vacuum metalizer, which is subjected to a vacuum down to a pressure of about 1×10⁻⁴ Torr or less to remove air from the chamber. Sputtering gas is then flowed into the chamber to a chamber pressure ranging between 1 mTorr and 25 mTorr, preferably between 1.5 mTorr and 10 mTorr. The preferred sputtering gas is argon but may be any other sputtering gas known in the art or a mixture of sputtering gases or a mixture of sputtering gas(es) and metal reducing gas(es), such as Argon-Hydrogen (Ar—H₂).

A metal/metal alloy sputter source, such as TORUS®, is placed within the vacuum metalizer and is supplied with electric power. The metal/metal alloy sputter source is typically a removable plug-and-play part inserted into the vacuum metalizer. Into the sputter source itself is inserted a removable plug-and-play part in the form of a plate, also known as the metal target, which contains the desired, to-be-deposited metal/metal alloy. The plate serves as a metal cathode during the sputtering operation. It is the plate/metal target that is bombarded with sputtering gas ions, preferably Argon ions, once electric power is supplied to the sputter source.

The plate/metal target in the processes described herein may contain any metal or metal alloy that results in desired reflective properties on the surface of the article. Suitable metals include aluminum, stainless steel, nickel, copper, silver, chromium, indium, and combinations of these. Aluminum is preferred because of its excellent reflective properties and low cost.

Metal sputtering begins when electric power is supplied to the metal target. Electric power may be supplied from an electric power source that operates, for example, on direct current [DC] (0 Hz frequency) or on audio frequency (several kHz frequency) or on radio frequency (13.56 MHz frequency). The electric power partially ionizes the sputtering gas. Cations of the gas discharge accelerate towards the negatively charged metal target and bombard its surface, thereby dislodging metal species. This dislodgement of metal species results in the vaporization of the metal and initiates vapor deposition onto an article placed before the metal target.

For the processes described herein, vapor deposition of the metal can occur at a maximum target power density of 60 W/cm² and for a maximum duration of 2 minutes. The choice of target power density and duration of applied power should be done so that these properties augment each together to provide a reflective metal coating that has a diffuse reflectance of less than or equal to 2% and a specular reflectance of more than or equal to 80%. If the target power density is too low, an insufficient quantity of metal vapor will be generated to properly coat the polymeric substrate in a reasonable duration, or the impurity level within the metal layer could be too high. If the power density is too high, the surface of a thermally sensitive article could be degraded by the heat radiated by the discharge.

As a property, target power density takes into consideration the geometrical surface area of the metal target used as the cathode. The target power density for sputtering a metal coating onto the article ranges from a minimum of 10 W/cm² to a maximum of 60 W/cm², preferably between 10 W/cm² and 40 W/cm², more preferably between 10 W/cm² and 30 W/cm². Preferably, the duration ranges between 0.25 and 2 minutes; more preferably, between 0.25 and 1.5 minutes.

The article is then passed in front of or before the metal target. This means the article is passed in effect through the vaporized metal; and a thin layer of metal is deposited onto the article's surface. To be clear, placing an article in front of or before the metal target means the article is placed relative to the metal target such that surface of the article is exposed to, and can receive dislodged metal species from, the vaporized metal.

Passing the article in front of or before the target, that is, through the vaporized metal, may occur for any number of passes to result in an article having the desired thickness of metal coating. In the processes described herein, the article may be passed through the metal vapor a maximum number of 25 passes to obtain a metal coating of less than 200 nanometer (nm) thickness. Preferably, the number of passes ranges from 2 and 25, preferably between 2 and 10, more preferably between 2 and 9. Preferably, the thickness of the metal coating is less than or equal to 170 nm, and more preferably less than 100 nm, but greater than about 10 nm.

The pressure of the atmosphere in the vapor deposition chamber during metal deposition may range between 1 mTorr and 25 mTorr; preferably between 1.5 mTorr and 10 mTorr.

For reasons related to cost, the metal coated article, also termed the metalized article, is typically not removed from the vacuum deposition chamber or exposed to air before a protective overcoat is applied.

### Step (2): Vapor Depositing an Overcoat Comprising a Siloxane Composition

Step (2) occurs in a vapor deposition chamber and is done by the following substeps:

(c) replacing the sputtering gas in the vapor deposition chamber with flowing hexamethyl disiloxane [HMDSO];

(d) flowing the hexamethyl disiloxane to achieve a residence time within the vapor deposition chamber ranging between 1 second and 20 seconds; at a pressure ranging between 20 mTorr and 75 mTorr;

(e) sustaining a hexamethyl disiloxane discharge at a maximum power density ranging between 0.6 W/cm² and 3 W/cm² for a maximum duration ranging between 0.2 minutes and 3.3 minutes; and,

(f) exposing the article to the hexamethyl disiloxane discharge for a maximum ranging between 1 and 40 times, to result in an article having an overcoat comprising HMDSO of thickness less than 325 nm.

Once the article metalized in step (1) achieves a sufficient and/or desired metal thickness, the sputtering gas flow to the vapor deposition chamber is terminated and the deposition chamber pressure is reduced to remove excess sputtering gas. Specifically, the vapor deposition chamber is preferably pumped down to a pressure of between about 0.1 mTorr to about 1.0 mTorr in step 2(c).

The article need not be removed from the vapor deposition chamber after metallization since a siloxane composition, preferably HMDSO, is then flowed through the chamber to achieve a residence time, that is, the duration when the HMDSO is present in the deposition chamber to achieve the desired pressure, ranging between 1 second and 20 seconds, preferably between 1.5 seconds and 15 seconds, at a pressure ranging between 20 mTorr and 75 mTorr, preferably between 20 mTorr and 60 mTorr.

Once the desired HMDSO pressure is achieved, an HMDSO discharge is activated with the HMDSO discharge source, which partially ionizes the HMDSO. The cathode and anode in the discharge source used in this step may be aluminum, stainless steel, nickel, copper, carbon, and any combination of these. Other metals and metal combinations may be used as the anode and cathode in the discharge source so long as they do not affect the reflectance properties of the finished article. The anode and cathode need not be of the same material. As used herein, the term “HMDSO discharge source” refers to that device which, upon applying to the device a voltage exceeding the breakdown voltage for the specific gas flowed within the deposition chamber, causes a gas discharge.

The power density applied to the discharge source to sustain a hexamethyl disiloxane discharge ranges between 0.5 W/cm² and 3 W/cm², preferably between 0.6 W/cm² and 2.5 W/cm², and more preferably between 0.6 W/cm² and 2.2 W/cm². The metal coated polymeric substrate is then exposed to the hexamethyl disiloxane discharge for a maximum deposition duration ranging between 0.2 minutes and 3.3 minutes, preferably between 0.3 minutes and 3 minutes; and more preferably between 0.3 and 2 minutes.

When the power applicator requires an electrode, as has been described in the above paragraphs, the article is then exposed to the hexamethyl disiloxane discharge by passing it in front of the cathode-anode array for at least one pass, preferably multiple passes, until the desired thickness of the overcoat is obtained on the metal layer of the polymeric substrate, and no more than 40 times, preferably between 2 and 37 times, or between 2 and 15 times, or between 2 and 8 times, or between 2 and 6 times, or between 1 and 6 times.

The thickness of the overcoat comprising HMDSO overcoat is not more than 325 nm and may range between about 15 nm and 300 nm or between 10 nm and 300 nm or more preferably between about 10 nm and 220 nm. After exposing the article to the hexamethyl disiloxane discharge for a desired number of passes or for the desired overcoat thickness, the article comprises an overcoat comprising HMDSO on the metal layer of the polymeric substrate.

Although the above paragraphs have described sustaining a hexamethyl disiloxane discharge using a power applicator that requires an electrode, sustaining this discharge may also be done by a variety of power applicators, which are known to those of skill in the art and may include, for instance, power applicators applying 0 Hz (direct current [“DC”]), or 40 kHz (audio frequency [“AF”]) or 13.56 MHz (radio frequency [“RF”]), 950 MHz and 2.45 GHz (both microwave frequency [“MW”]). In particular, RF and MW power may be applied by electrodeless means. Thus, electrodeless power applications may be used to practice both steps in the processes described herein.

Achieving Thermal Stability: Determining Diffuse Reflectance of Less than or Equal to 2% and Visibly Line Free Surface

To be clear, the article has achieved the desired, recited result when its surface, metallized and coated according to recited steps (1) and (2) as described above, is both visibly line free and has a diffuse reflectance of less than 2%, as measured at 600 nm by a conventional reflectance method comprising ASTM C1650-07.

To determine that the coated surface of an article has achieved the desired, recited result, the article is heated to a maximum temperature between 165° C. and 190° C. for at least one hour and up to twenty-four (24) hours in a conventional air oven. The maximum temperature of these processes includes every possible integer value and every possible decimal value within the range between 165° C. and 190° C. Some examples include: 165.5, 170.2, 173, 176.82, 177.01, 180.55, etc. The heating duration may range between one and four hours, preferably. The diffuse reflectance is then measured and the surface of the article observed with the naked eye. The spectral reflectance of the article may also be measured.

This heating serves to qualitatively demonstrate thermal endurance of the coated surface, Thermal endurance is believed to indicate the thermal stability of the coated surface. As used herein, the term “thermal stability” of a surface refers to the ability of the surface, when exposed to widely varying temperatures, to accommodate the strain mismatch between the coating and the substrate without forming visually (human eye) observable surface features.

Not being bound by any theory, it is hypothesized that, when the coated surface, upon achieving a temperature of between 165° C. and 190° C. for at least one hour, obtains diffuse reflectance less than or equal to 2% with a visibly line free appearance, the coated surface has achieved relative thermal stability.

The diffuse reflectance and/or specular reflectance of the article is determined using a spectrophotometer using ASTM C1650-07. One such spectrophotometer is a Color-Eye® 7000A reference spectrophotometer available from Gretag Macbeth, New Windsor, N.Y. The reflectance is dependent on the wave length used to measure it. For the processes described herein, reflectance is measured at 600 nm by a conventional reflectance method comprising ASTM C1650-07. For the diffuse reflectance, the desired, recited result is less than or equal to 2%. For the spectral reflectance, the desired, recited result is greater than or equal to 80%.

A visibly line free surface is observed by the human eye to be without features having the appearance of a line, or a streak, or a row, or a stripe, or a linear contour that is longer than 1 millimeter (1 mm) In other words, the visibly line free surface lacks features that look to the human eye like a line longer than 1 millimeter (mm), but may possess other types of visually apparent features such as dots, spots, points, specks, blotches, freckling, etc., less than 1 mm of longest dimension.

To be clear, the processes described herein may involve heating the article to a maximum temperature between 165° C. and 190° C. in one or more heating treatments. For example, the article may be heated to a temperature of 165° C. for between one and four hours, and then be subsequently heated to a temperature of 190° C. for between one and twenty-four hours. Thus, these processes expressly include either a single heating or multiple heatings of the coated article to a maximum temperature between 165° C. and 190° C. for at least one hour and up to 24 hours. Thus, a subsequent heating treatment may serve as a more stringent demonstration of thermal endurance (and hence thermal stability) of the surface coating. That is, when articles coated by these processes are subsequently heated to a higher maximum temperature within the range of 165° C. and 190° C. and still demonstrate a visibly line free surface that has diffuse reflectance, less than or equal to 2%, it is believed that the surface coating more plainly exhibits thermal endurance.

### Before Step 1: Pre-Conditioning the Vapor Deposition Chamber

The processes described herein may also comprise a step before step 1, which is a pre-conditioning step in which the interior of the vapor deposition chamber retains species derived from the most recent hexamethyl disiloxane discharge done in the chamber and from the exposure of the interior of the vapor deposition chamber to ambient humidity during the unloading and loading of articles. These species are termed herein “leftover species”. Not being bound by any theory, it is hypothesized that the participation of leftover species in the Al sputtering process influences the performance of the Al/substrate interface to accommodate the strain mismatch between the coating and the substrate, and the thermal stability of the Al layer. In particular, Tables 24 and 25 show the specific influences of the steps and sub-steps in the processes described herein.

### Compositions of Articles Metalized in the Processes Described Herein

The articles to be metalized in the processes described herein may comprise any semi-crystalline polymer composition capable of withstanding temperatures to which the article is exposed during use, especially above 150° C. Such compositions may include polyamides and/or polyesters as the semi-crystalline polymer. The preferred polymer is semi-crystalline polyester, which includes polyester homopolymers, copolymers and mixtures of these.

Semi-crystalline polyesters typically are made of one or more dicarboxylic acid and diol. Suitable dicarboxylic acids (and their corresponding esters) include terephthalic acid, isophthalic acid, naphthalene dicarboxylic acids, cyclohexane dicarboxylic acids, succinic acid, glutaric acid, adipic acid, sebacic acid, 1,12-dodecane dioic acid, fumaric acid, maleic acid, and derivatives of these, such as, the dimethyl, diethyl, or dipropyl esters.

Suitable glycols that may constitute the diol component include ethylene glycol, 1,3-propylene glycol, 1,2-propylene glycol, 2,2-diethyl-1,3-propane diol, 2,2-dimethyl-1,3-propane diol, 2-ethyl-2-butyl-1,3-propane diol, 2-ethyl-2-isobutyl-1,3-propane diol, 1,3-butane diol, 1,4-butane diol, 1,5-pentane diol, 1,6-hexane diol, 2,2,4-trimethyl-1,6-hexane diol, 1,2-cyclohexane dimethanol. 1,3-cyclohexane dimethanol, 1,4-cyclohexane dimethanol, 2,2,4,4-tetramethyl-1,3-cyclobutane diol, isosorbide, naphthalene glycols, diethylene glycol, triethylene glycol, resorcinol, hydroquinone, as well as longer chain diols and polyols, such as polytetramethylene ether glycol, which are the reaction products of diols or polyols with alkylene oxides.

In a preferred polyester, the dicarboxylic acids comprise one or more of terephthalic acid, isophthalic acid and 2,6-naphthalene dicarboxylic acid, and the diol component comprises one or more of HO(CH₂₎ₙOH (I), 1,4-cyclohexanedimethanol, HO(CH₂CH2O)ₘCH₂CH₂OH (II), and HO(CH₂CH₂CH₂CH₂O)_{z}CH₂CH₂CH₂CH₂OH (III), wherein n is an integer of 2 to 10, m is on average 1 to 4, and z is an average of about 7 to about 40. Note that (II) and (III) may be a mixture of compounds in which m and z, respectively, may vary and hence since m and z are averages, they need not be integers. In preferred polyesters, n is 2, 3 or 4, and/or m is 1.

Specific preferred polyesters include without limitation poly(ethylene terephthalate) (PET), poly(trimethylene terephthalate) (PTT), poly(1,4-butylene terephthalate) (PBT), poly(ethylene 2,6-naphthoate) (PEN), and poly(1,4-cyclohexyldimethylene terephthalate) (PCT) and copolymers and blends of the same. Of these, the preferred thermoplastic polyesters are selected from poly(ethylene terephthalate) (PET), poly(trimethylene terephthalate) (PTT), poly(1,4-butylene terephthalate) (PBT), poly(1,4-cyclohexyldimethylene terephthalate) (PCT), and copolymers and blends of the same. Poly(ethylene terephthalate), poly(1,4-butylene terephthalate), and poly(1,4-butylene terephthalate) are preferred.

Suitable polyesters for use in the invention are commercially available under the trade names Rynite® poly(ethylene terephthalate) polyester resins, Crastin® PBT polyester resins, and Sorona®, all available from E.I. du Pont de Nemours and Co., Wilmington, Del.

The semi-crystalline polyester compositions of articles metalized by the processes described herein may also contain a lubricant selected from the group consisting of long chain fatty acid esters of organic polyols and their salts. Examples include, but are not limited to, pentaerythritol tetramontanoate, dipentaerythritol hexastearate, and sodium montanate, and any mixture of these.

The semi-crystalline polymer compositions useful in articles metalized by these processes may further comprise additives and fillers, which include but are not limited to, calcium carbonate, carbon fibers, carbon black, talc, mica, wollastonite, calcinated clay, kaolin, magnesium sulfate, magnesium silicate, barium sulfate, titanium dioxide, sodium aluminum carbonate, barium ferrite, potassium titanate, and other mineral fillers. The semi-crystalline polymer compositions need not further comprise these additives and fillers. The concentration of carbon black or carbon fibers may range from 0 weight percent to about 2 weight percent of the semi-crystalline polymer composition. The concentration of mineral filler may range from 0 to about 15 weight percent of the semi-crystalline polymer composition.

### Making Articles Metalized by Processes Described Herein

The processes described herein result in metalized articles, wherein the articles have surfaces that are visibly line free and have a diffuse reflectance of less than or equal to 2%, as measured at 600 nm by a conventional reflectance method comprising ASTM C1650-07.

Articles suitable for use in the processes described herein may be prepared by any molding method available in the art such as injection molding, blow molding, compression molding. By undergoing steps (1) and (2) of the processes described herein, articles either already molded or during molding may achieve visibly line free surfaces with diffuse reflectance of less than or equal to 2% and a specular reflectance of greater than or equal to 80%, as measured at 600 nm by ASTM C1650-7 or a reflectance method associated with a particular spectrophotometer.

Consequently, suitable articles for metalizing by these processes include vehicle light bezels, such as tail light bezels, head light bezels, directional light bezels, and interior light bezels. Other suitable articles include street lights, flood lights, and any other article that is metalized in order to reflect light.

### EXAMPLES

### Materials

Semi-crystalline polymer: DuPont Crastin® CE2055 BK580 unreinforced PBT based molding resin.

Aluminum Target: purity=99.999%, available from Williams Advanced Materials, Buffalo, N.Y.

Sputtering Gas: Argon—4% H₂ gas, available from GTS-Welco, Morrisville, Pa.

HMDSO: purity=98+% available from Aldrich Chemistry, St. Louis, Mo.

### Methods

### Methods of Preparing Samples: Generic Protocol

CE2055 BK580 plaques, nominally measuring 6″×3″×3 mm, were injection molded with a FN4000 molding machine using barrel and melt temperatures of 250° C. and 258° C., respectively, a water moderated mold temperature of 50° C., and an overall molding cycle of about 70 seconds.

Vapor depositions were carried out in a stainless steel vacuum chamber having its wall temperature thermostatically controlled at 50° C.±2° C. Plaques were placed onto a holder, and the holder was then rotated at a selected speed. The chamber was then evacuated down to a pressure of about 1 mTorr with a mechanical pumping system that included a Roots blower and a rotary vane pump. An LN2 trap was fitted between the chamber and the pumping system. The pumping was then switched to a cryo-pump to attain a base pressure of about 1.8E-5 Torr. A mixture of Ar-4% H₂ was then admitted into the chamber and the cryo-pump was throttled to achieve a process pressure of about 10 mTorr. A circular TORUS® sputter source available from Kurt J. Lesker Co., Pittsburgh, Pa., using a 2 inch (about 5 cm) diameter aluminum target of 99.999% purity available from Williams Advanced Materials, Buffalo, N.Y. was powered with a DC power generator manufactured by Advanced Energy, Fort Collins, Colo., model MDX-1.5k, to execute the Al vapor deposition for a prescribed period of time. The inlet valve for the Ar-4% H₂ mixture was closed and the chamber was evacuated with the cryo-pump to a pressure of below 1 mTorr, and then the chamber was pumped with the mechanical pumping system. HMDSO available from Aldrich Chemistry, St. Louis, Mo., with a purity of 98+% was contained in a heated reservoir held at 80° C. to increase the HMDSO vapor pressure, so that it could be delivered into the chamber. Such delivery was done through heated transfer lines thermostatically held at 110° C. to eliminate vapor condensation on the walls of the transfer lines. A circular TORUS® sputter source available from Kurt J. Lesker Company, Pittsburgh, Pa., using 2 inch (about 5 cm) diameter carbon target was powered with either a 40 kHz power generator, model PE-1000, or with a 13.56 MHz power generator, model Cesar®, both manufactured by Advanced Energy, Fort Collins, Colo., to execute the HMDSO plasma-enhanced chemical vapor deposition step. The TORUS® sputter sources used for both the Al process and the HMDSO process used aluminum anodes.

Following vapor deposition, the plaques were treated in a stagnant air oven, Lindberg/Blue M, model # V012180A, available from Thermo Electron Corporation, Marietta, Ohio, which was held at 170° C.±5° C.

Plaques having D≦2% and S≧80% were further treated in a stagnant air oven supplied by Fisher, model #281, which was held at 190° C.±5° C.

### Determination of Aluminum (“Al”) Layer Thicknesses

Conventional 3 inch×1 inch (about 7.5 cm×2.5 cm) glass slides having a 1-mm wide contact mask were sputter vapor deposited with Al under various levels of target power density and deposition time. Following removal of the contact mask, the samples were sputter vapor deposited again with a layer of aluminum having a nominal thickness of about 100 nm. The depth of the so-formed, 1-mm wide trenches—equivalent to layer thickness—were measured using profilometric analysis.

Alternatively, the Al layers were removed via digestion into HCl aliquots, which were then analyzed for Al content using the Inductively Coupled Plasma technique in which HCl aliquots were prepared as follows:

1. using fine grit sandpaper, any aluminum coating deposited on the sides and back face of a sample was removed, and the sample cleaned with either a lint free cloth and/or distilled water to remove all particulate,
2. the length and width of the sample was measured and recorded,
3. in a fume hood, the plaque was placed in a vial, and each vial was labeled according to the plaque number,
4. the vial containing a plaque was filled with fresh HCl (full strength, 12 molar) until the plaque was fully submerged, and the amount of used HCl was recorded,
5. the plaque was kept submerged in the liquid until the coating is fully dissolved,
6. once digestion was complete, the plaque was carefully removed from the vial and rinsed with water.
7. the HCl solution was carefully transferred to a thick wall glass bottle,
8. a bland was created by transferring HCl directly from the container into a thick wall glass bottle, which was properly labeled.

Both techniques, profilometry of trenches and Inductively Coupled Plasma technique of HCl aliquots, gave comparable results. For samples coated with Al/HMDSO bilayers, the Al content was determined with the Inductively Coupled Plasma technique of HCl aliquots.

### Determination of HMDSO Overcoat Thickness

Conventional 3 inch×1 inch (about 7.5 cm×2.5 cm) glass slides having a 1-mm wide contact mask were vapor deposited using the HMDSO overcoat deposition step under various levels of electrode power density, deposition time and process pressure. Following removal of the contact mask, the samples were sputter vapor deposited with a layer of aluminum having a nominal thickness of about 100 nm. The depth of the thus-formed 1-mm wide trenches was measured using profilometric analysis.

For samples coated with Al/HMDSO bilayers, the overcoat thickness was measured as the difference between the thickness of the Al/HMDSO bilayer and the thickness of the Al layer. The Al/HMDSO bilayer thickness was determined by profilometric analysis, whereas the Al layer thickness was determined by the HCl aliquot technique.

### Discussion of the Tables

In the Tables below, examples are denoted by “E” and comparative examples by “C”. The collective goal of presenting the tables is to demonstrate that the achievement of D≦2% and S≧80% depends NOT on a single variable, but on combinations of all variables. In Tables 1 to 21 below, the comparative examples illustrate process conditions having a very high D (diffuse reflectance) or a very low S (specular reflectance).

Each of tables 1 to 10 below depicts the variation in one variable versus the achieved D or S after heating to 170° C. for one hour, whereas Table 11 depicts the variation in all measured variables versus the achieved D or S after heating to and subsequent heating to 190° C. for 1 hour. For Tables 1 to 11, the HMDSO overcoat deposition step was executed with a 40 kHz power generator.

Similarly, each of tables 12 to 20 below depicts the variation in one variable versus the achieved D or S after air treatment at 170° C. for one hour, whereas Table 21 depicts the variation in all measured variables versus the achieved D or S after heating to 170° C. for 1 hour and subsequent heating to 190° C. for 1 hour. For Tables 12 to 20, the HMDSO overcoat deposition step was executed with a 13.56 MHz power generator.

Thus, each of tables 1 to 21 tabulates values of process conditions based on variation in one variable to individually account for the achievement of D≦2% and S≧80%. Collectively, tables 1 to 21 demonstrate that variations in one variable only did NOT account for the achieved D or S.

### Tables 1 to 11

Tables 1 to 11 below depict variation in one variable versus the achieved D or S upon executing

the HMDSO overcoat deposition step with a 40 kHz power generator.

TABLE 1
Table 1. Reflectance performance after heating to 170° C. for 1 hour using
process conditions comprising similar measures of Al target power density for:
E1; C1 and C2, similar high power density; E2; C3 and C4, similar low power density.

| | | High Target Power Density | | | Low Target Power Density | | |
|---|---|---|---|---|---|---|---|
| | | | High D | Low S | | High D | Low S |
| | | E1 | C1 | C2 | E2 | C3 | C4 |
| Al Process | Power density (W/cm²) | 37.7 | 37.2 | 37.7 | 14.1 | 14.1 | 14.2 |
| | Deposition time (min) | 0.50 | 0.50 | 0.50 | 1.00 | 1.00 | 1.00 |
| | Number of Passes | 4.3 | 7.5 | 4.3 | 4.0 | 15.0 | 15.0 |
| | Al Thickness (nm) | 78 | 77 | 78 | 56 | 56 | 57 |
| HMDSO | Residence time (s) | 1.9 | 1.9 | 11.4 | 5.7 | 5 | 1.9 |
| Process | Pressure (mTorr) | 30 | 30 | 60 | 30 | 30 | 30 |
| (40 kHz) | Power density (W/cm²) | 1.73 | 1.73 | 1.73 | 0.78 | 0.78 | 0.78 |
| | Deposition time (min) | 3.00 | 0.75 | 3.00 | 1.50 | 0.75 | 1.50 |
| | HMDSO Thickness (nm) | 80 | 17 | 80 | 22 | 10 | 22 |
| | Number of Passes | 25.8 | 11.0 | 25.8 | 6.0 | 11.3 | 22.5 |
| 170° C./1 hr | D (%) | 1.4 | 3.9 | 30.1 | 1.3 | 4.0 | 2.6 |
| Performance | S (%) | 84.5 | 80.3 | 74.4 | 82.4 | 81 | 78.5 |

Table 1 shows that the achievement of D≦2% and S≧80% after air treatment to 170° C. for 1 hour did NOT solely depend on the Al target power density.

TABLE 2
Table 2. Reflectance performance after heating to 170° C. for 1 hour
using process conditions comprising similar measures of Al deposition time
for: E3; C5 and C6, similar long time; and E4; C7 and C8, similar short time.

| | | Long Al Deposition Time | | | Short Al Deposition Time | | |
|---|---|---|---|---|---|---|---|
| | | | High D | Low S | | High D | Low S |
| | | E3 | C5 | C6 | E4 | C7 | C8 |
| Al Process | Power density (W/cm²) | 28.5 | 28.8 | 28.6 | 34.9 | 30.9 | 36.2 |
| | Deposition time (min) | 1.0 | 1.0 | 1.0 | 0.5 | 0.5 | 0.5 |
| | Number of Passes | 4.0 | 15.0 | 4.0 | 4.3 | 4.3 | 4.3 |
| | Al Thickness (nm) | 111 | 113 | 112 | 73 | 65 | 75 |
| HMDSO | Residence time (s) | 5.0 | 5.7 | 1.9 | 1.9 | 11.4 | 11.4 |
| Process | Pressure (mTorr) | 30 | 30 | 30 | 30 | 60 | 60 |
| (40 kHz) | Power density (W/cm²) | 1.4 | 1.73 | 1.73 | 1.62 | 1.22 | 1.62 |
| | Deposition time (min) | 0.75 | 0.72 | 0.75 | 3.0 | 1.50 | 3.00 |
| | HMDSO Thickness (nm) | 17 | 17 | 17 | 75 | 30 | 75 |
| | Number of Passes | 3.0 | 11.0 | 3.0 | 25.8 | 12.9 | 25.8 |
| 170° C./1 hr | D (%) | 1.5 | 3.1 | 3.0 | 1.0 | 3.5 | 3.3 |
| Performance | S (%) | 84 | 81.2 | 77 | 84.0 | 79.7 | 74.1 |

Table 2 shows that the achievement of D≦2% and S≧80% after heating to 170° C. for 1 hour did NOT solely depend on the Al deposition time.

TABLE 3
Table 3. Reflectance performance after heating to 170° C. for 1 hour using
process conditions comprising similar number of passes during the Al process for:
E5; C9 and C10, similar large number; and E6; C11 and C12, similar small number.

| | | Large Al Number of Passes | | | Small Al Number of Passes | | |
|---|---|---|---|---|---|---|---|
| | | | High D | Low S | | High D | Low S |
| | | E5 | C9 | C10 | E6 | C11 | C12 |
| Al Process | Power density (W/cm²) | 20.1 | 19.8 | 27.4 | 37.3 | 30.6 | 33.8 |
| | Deposition time (min) | 1.00 | 1.00 | 1.00 | 0.50 | 0.50 | 0.50 |
| | Number of Passes | 15.0 | 15.0 | 15.0 | 2.0 | 2.0 | 2.0 |
| | Al Thickness (nm) | 79 | 78 | 107 | 77 | 64 | 70 |
| HMDSO | Residence time (s) | 5.7 | 5.0 | 1.9 | 1.9 | 1.9 | 1.9 |
| Process | Pressure (mTorr) | 30 | 30 | 60 | 30 | 30 | 30 |
| (40 kHz) | Power density (W/cm²) | 1.01 | 1.01 | 1.57 | 1.73 | 1.22 | 1.40 |
| | Deposition time (min) | 0.72 | 0.75 | 1.50 | 0.75 | 0.75 | 1.50 |
| | HMDSO Thickness (nm) | 12 | 12 | 35 | 17 | 14 | 32 |
| | Number of Passes | 10.8 | 11.0 | 22.5 | 3.0 | 3.0 | 6.0 |
| 170° C./1 hr | D (%) | 2.0 | 4.0 | 4.0 | 1.5 | 2.6 | 1.8 |
| Performance | S (%) | 83 | 81 | 74 | 83 | 83 | 77 |

Table 3 shows that the achievement of D≦2% and S≧80% after heating to 170° C. for 1 hour did NOT solely depend on the number of passes during the Al deposition step.

TABLE 4
Table 4. Reflectance performance after heating to 170° C. for 1 hour using
process conditions comprising similar thickness of deposited Al for: E7; C13 and
C14, similar large Al thickness; and E8; C15 and C16, similar small Al thickness.

| | | Large Al Thickness | | | Small Al Thickness | | |
|---|---|---|---|---|---|---|---|
| | | | High D | Low S | | High D | Low S |
| | | E7 | C13 | C14 | E8 | C15 | C16 |
| Al Process | Power density (W/cm²) | 28.5 | 37.2 | 37.2 | 25.3 | 19.8 | 13.3 |
| | Deposition time (min) | 1.0 | 0.75 | 0.75 | 0.50 | 0.67 | 1.00 |
| | Number of Passes | 4.0 | 11.3 | 11.3 | 4.3 | 10.0 | 8.6 |
| | Al Thickness (nm) | 111 | 111 | 111 | 53 | 54 | 53 |
| HMDSO | Residence time (s) | 5.0 | 5.7 | 1.9 | 1.9 | 5.0 | 5.7 |
| Process | Pressure (mTorr) | 30 | 30 | 30 | 30 | 30 | 30 |
| (40 kHz) | Power density (W/cm²) | 1.73 | 1.73 | 1.73 | 1.22 | 1.01 | 1.22 |
| | Deposition time (min) | 0.75 | 1.50 | 1.50 | 3.00 | 0.75 | 3.00 |
| | HMDSO Thickness (nm) | 17 | 37 | 37 | 56 | 12 | 56 |
| | Number of Passes | 3.0 | 23.0 | 22.5 | 25.8 | 11.3 | 25.8 |
| 170° C./1 hr | D (%) | 1.5 | 3.9 | 2.4 | 1.4 | 3.8 | 2.6 |
| Performance | S (%) | 84 | 76 | 73 | 84 | 80 | 73 |

Table 4 shows that the achievement of D≦2% and S≧80% after heating to 170° C. for 1 hour did NOT solely depend on the Al thickness.

TABLE 5
Table 5. Reflectance performance after heating to 170° C. for 1 hour using process
conditions comprising residence time in the HMDSO overcoat deposition step for: E9; C17
and C18, similar long residence time; and E10: C19 and C20. similar short residence time.

| | | Long Residence Time | | | Short Residence Time | | |
|---|---|---|---|---|---|---|---|
| | | | High D | Low S | | High D | Low S |
| | | E9 | C17 | C18 | E10 | C19 | C20 |
| Al Process | Power density (W/cm²) | 25.6 | 25.9 | 13.4 | 25.3 | 30.6 | 25.3 |
| | Deposition time (min) | 1.00 | 1.00 | 1.00 | 0.50 | 0.50 | 0.50 |
| | Number of Passes | 8.6 | 8.6 | 8.6 | 4.3 | 7.5 | 4.3 |
| | Al Thickness (nm) | 100 | 102 | 53 | 53 | 64 | 53 |
| HMDSO | Residence time (s) | 5.7 | 11.4 | 5.7 | 1.9 | 1.9 | 1.9 |
| Process | Pressure (mTorr) | 30 | 60 | 30 | 30 | 30 | 30 |
| (40 kHz) | Power density (W/cm²) | 1.40 | 1.40 | 1.22 | 1.22 | 1.22 | 1.22 |
| | Deposition time (min) | 1.50 | 1.50 | 3.0 | 3.0 | 0.75 | 3.0 |
| | HMDSO Thickness (nm) | 32 | 32 | 56 | 56 | 14 | 56 |
| | Number of Passes | 12.9 | 13 | 25.8 | 25.8 | 11.3 | 25.8 |
| 170° C./1 hr | D (%) | 1.8 | 3.7 | 2.2 | 1.4 | 4.0 | 2.5 |
| Performance | S (%) | 80 | 79 | 70 | 84 | 81 | 75 |

Table 5 shows that the achievement of D≦2% and S≧80% after heating to 170° C. for 1 hour did NOT solely depend on the residence time.

TABLE 6
Table 6. Reflectance performance after heating to 170° C. for 1 hour using process
conditions comprising similar pressure in the HMDSO overcoat deposition step for: E11;
C21 and C22, similar high pressure: and E12; C23 and C24, similar low pressure.

| | | High Pressure | | | Low Pressure | | |
|---|---|---|---|---|---|---|---|
| | | | High D | Low S | | High D | Low S |
| | | E11 | C21 | C22 | E12 | C23 | C24 |
| Al Process | Power density (W/cm²) | 25.6 | 28.3 | 29.3 | 36.3 | 30.6 | 37.2 |
| | Deposition time (min) | 0.67 | 0.67 | 0.67 | 0.5 | 0.5 | 0.75 |
| | Number of Passes | 5.7 | 5.7 | 5.7 | 4.3 | 7.5 | 11.3 |
| | Al thickness (nm) | 70 | 77 | 79 | 76 | 64 | 111 |
| HMDSO | Residence time (s) | 11.4 | 11.4 | 11.4 | 1.9 | 1.9 | 1.9 |
| Process | Pressure (mTorr) | 60 | 60 | 60 | 30 | 30 | 30 |
| (40 kHz) | Power density (W/cm²) | 1.73 | 1.73 | 1.73 | 1.73 | 1.22 | 1.73 |
| | Deposition time (min) | 3 | 1.5 | 3 | 3 | 0.75 | 1.5 |
| | HMDSO thickness (nm) | 70 | 37 | 80 | 80 | 14 | 37 |
| | Number of Passes | 25.8 | 13.0 | 25.8 | 25.8 | 11.3 | 22.5 |
| 170° C./1 hr | D (%) | 1.5 | 3.6 | 1.5 | 0.9 | 4 | 2.4 |
| Performance | S (%) | 80 | 79 | 74 | 84 | 81 | 73 |

Table 6 shows that the achievement of D≦2% and S≧80% after heating to 170° C. for 1 hour did NOT solely depend on the pressure in the HMDSO overcoat deposition step.

TABLE 7
Table 7. Reflectance performance after heating to 170° C. for 1 hour
using process conditions comprising similar electrode power density in the
HMDSO overcoat deposition step for: E13; C25 and C26, similar high electrode
power density; and E14; C27 and C28, similar low electrode power density.

| | | High Electrode Power Density | | | Low Electrode Power Density | | |
|---|---|---|---|---|---|---|---|
| | | | High D | Low S | | High D | Low S |
| | | E13 | C25 | C26 | E14 | C27 | C28 |
| Al Process | Power density (W/cm²) | 19.31 | 37.2 | 37.2 | 18.5 | 18.5 | 9.5 |
| | Deposition time (min) | 1.00 | 0.75 | 0.75 | 0.75 | 0.75 | 1.50 |
| | Number of Passes | 8.6 | 11.3 | 11.3 | 3.0 | 11.3 | 12.9 |
| | Al Thickness (nm) | 76 | 111 | 111 | 57 | 57 | 55 |
| HMDSO | Residence time (s) | 1.9 | 5.7 | 1.9 | 5.7 | 5.7 | 5.7 |
| Process | Pressure (mTorr) | 30 | 30 | 0 | 30 | 30 | 30 |
| (40 kHz) | Power density (W/cm²) | 1.73 | 1.73 | 1.73 | 0.78 | 0.78 | 0.78 |
| | Deposition time (min) | 3.00 | 1.50 | 1.50 | 1.50 | 1.50 | 1.50 |
| | HMDSO Thickness (nm) | 80 | 37 | 37 | 22 | 22 | 22 |
| | Number of Passes | 25.8 | 23.0 | 22.5 | 6.0 | 22.5 | 12.9 |
| 170° C./1 hr | D (%) | 0.9 | 3.9 | 2.4 | 0.9 | 3.6 | 3.0 |
| Performance | S (%) | 85 | 76 | 73 | 82 | 79 | 74 |

Table 7 shows that the achievement of D≦2% and S≧80% after heating to 170° C. for 1 hour did NOT solely depend on the electrode power density in the HMDSO overcoat deposition step.

TABLE 8
Table 8. Reflectance performance after heating to 170° C. for 1 hour using
process conditions comprising similar HMDSO overcoat deposition time for: E15;
C29 and C30, similar long time: and E16; C31 and C32, similar short time.

| | | Long HMDSO Deposition Time | | | Short HMDSO Deposition Time | | |
|---|---|---|---|---|---|---|---|
| | | | High D | Low S | | High D | Low S |
| | | E15 | C29 | C30 | E16 | C31 | C32 |
| Al Process | Power density (W/cm²) | 19.1 | 18.4 | 13.4 | 20 | 30.6 | 27.4 |
| | Deposition time (min) | 1.00 | 1.00 | 1.00 | 0.67 | 0.50 | 1.00 |
| | Number of Passes | 8.6 | 8.6 | 8.6 | 2.7 | 7.5 | 7.0 |
| | Al Thickness (nm) | 76 | 73 | 53 | 55 | 64 | 107 |
| HMDSO | Residence time (s) | 1.9 | 5.7 | 5.7 | 1.9 | 1.9 | 1.9 |
| Process | Pressure (mTorr) | 30 | 30 | 30 | 30 | 30 | 30 |
| (40 kHz) | Power density (W/cm²) | 1.73 | 1.62 | 1.22 | 1.01 | 1.22 | 1.57 |
| | Deposition time (min) | 3.00 | 3.00 | 3.00 | 0.75 | 0.75 | 0.75 |
| | HMDSO Thickness (nm) | 80 | 73 | 56 | 12 | 14 | 16 |
| | Number of Passes | 25.8 | 26.0 | 25.8 | 3.0 | 11.3 | 3.0 |
| 170° C/1 hr | D (%) | 0.9 | 3.9 | 2.2 | 1.1 | 4.0 | 2.6 |
| Performance | S (%) | 85 | 75 | 70 | 84 | 81 | 77 |

Table 8 shows that the achievement of D≦2% and S≧80% after heating to 170° C. for 1 hour did NOT solely depend on the HMDSO overcoat deposition time.

TABLE 9
Reflectance performance after heating to 170° C. for 1 hour using process conditions
comprising similar HMDSO overcoat thickness for:
E17; C33 and C34, similar large HMDSO overcoat thickness; and
E18; C35 and C36, similar small HMDSO overcoat thickness.

| | | Large HMDSO Thickness | | | Small HMDSO Thickness | | |
|---|---|---|---|---|---|---|---|
| | | | High D | Low S | | High D | Low S |
| Table 9 | | E17 | C33 | C34 | E18 | C35 | C36 |
| Al Process | Power density (W/cm²) | 27.6 | 37.7 | 37.7 | 20.0 | 19.8 | 20.0 |
| | Deposition time (min) | 0.67 | 0.50 | 0.50 | 0.67 | 1.00 | 0.67 |
| | Number of Passes | 5.7 | 4.3 | 4.3 | 2.7 | 15.0 | 2.7 |
| | Al Thickness (nm) | 75 | 78 | 78 | 55 | 78 | 55 |
| HMDSO | Residence time (s) | 5.7 | 11.4 | 11.4 | 1.9 | 5.0 | 5.7 |
| Process (40 | Pressure (mTorr) | 30 | 60 | 60 | 30 | 30 | 30 |
| kHz) | Power density (W/cm²) | 1.73 | 1.73 | 1.73 | 1.01 | 1.01 | 1.01 |
| | Deposition time (min) | 3.00 | 3.00 | 3.00 | 0.75 | 0.75 | 0.75 |
| | HMDSO Thickness (nm) | 80 | 80 | 80 | 12 | 12 | 12 |
| | Number of Passes | 25.8 | 26 | 25.8 | 3.0 | 11.3 | 3.0 |
| 170° C./1 hr | D (%) | 1.0 | 3.1 | 3.1 | 1.1 | 4.0 | 3.8 |
| Performance | S (%) | 87 | 74 | 74 | 84 | 81 | 79 |

Table 9 shows that the achievement of D≦2% and S≧80% after heating to 170° C. for 1 hour did NOT solely depend on the HMDSO thickness.

TABLE 10
Table 10. Reflectance performance after heating to 170° C. for 1
hour using process conditions comprising similar number of passes in
the HMDSO overcoat deposition step for: E19; C37 and C38, similar large
number of passes; and E20: C39 and C40, similar small number of passes.

| | | Large Number of Passes | | | Small Number of Passes | | |
|---|---|---|---|---|---|---|---|
| | | | High D | Low S | | High D | Low S |
| | | E19 | C37 | C38 | E20 | C39 | C40 |
| Al Process | Power density (W/cm²) | 19.1 | 17.4 | 13.4 | 25.8 | 33.5 | 27.4 |
| | Deposition time (min) | 1.00 | 1.00 | 1.00 | 1.00 | 0.75 | 1.00 |
| | Number of Passes | 8.6 | 8.6 | 8.6 | 4.0 | 3.0 | 4.0 |
| | Al Thickness (nm) | 76 | 69 | 53 | 101 | 101 | 107 |
| HMDSO | Residence time (s) | 1.9 | 5.7 | 5.7 | 5.0 | 1.9 | 1.9 |
| Process | Pressure (mTorr) | 30 | 30 | 30 | 30 | 30 | 30 |
| (40 kHz) | Power density (W/cm²) | 1.73 | 1.51 | 1.22 | 1.40 | 1.40 | 1.57 |
| | Deposition time (min) | 3.00 | 3.00 | 3.00 | 0.75 | 0.75 | 0.75 |
| | HMDSO Thickness (nm) | 80 | 70 | 56 | 15 | 15 | 16 |
| | Number of Passes | 25.8 | 26 | 25.8 | 3.0 | 3.0 | 3.0 |
| 170° C./1 hr | D (%) | 0.9 | 3.8 | 2.2 | 1.1 | 3.9 | 2.6 |
| Performance | S (%) | 85 | 75 | 70 | 85 | 80 | 77 |

Table 10 shows that the achievement of D≦2% and S≧80% after heating to 170° C. for 1 hour did NOT solely depend on the number of passes in the HMDSO overcoat deposition step.

TABLE 11
Table 11. Reflectance performance after heating to at 170° C. for 1 hour and subsequent heating to 190° C. for 1 hour for:
E21 through E27; C41 through C61, illustrating the range for each process variable.

| | | | | | HMDSO Process | | | | | | 170° C./ | |
|---|---|---|---|---|---|---|---|---|---|---|---|---|
| | Al Process | | | | (40 kHz) | | | | | | 1 hr + 190° C./ | |
| | Power | | Number | Al | | | Power | | HMDSO | Number | 1 hr | |
| | density | Deposition | of | Thickness | Residence | Pressure | density | Deposition | Thickness | of | Performance | |
| | (W/cm²) | time (min) | Passes | (nm) | time (s) | (mTorr) | (W/cm²) | time (min) | (nm) | Passes | D (%) | S (%) |
| E21 | 23.5 | 0.67 | 5.7 | 64 | 5.7 | 30 | 1.37 | 3.0 | 63 | 25.8 | 1.7 | 82 |
| E22 | 25.8 | 0.67 | 5.7 | 70 | 5.7 | 30 | 1.51 | 3.0 | 70 | 25.8 | 1.1 | 84 |
| E23 | 27.2 | 0.67 | 5.7 | 74 | 5.7 | 30 | 1.62 | 3.0 | 75 | 25.8 | 1.6 | 84 |
| E24 | 28.3 | 0.67 | 5.7 | 77 | 5.7 | 30 | 1.73 | 3.0 | 80 | 25.8 | 1.7 | 84 |
| E25 | 31.2 | 0.50 | 4.3 | 65 | 1.9 | 30 | 1.37 | 3.0 | 63 | 25.8 | 1.7 | 82 |
| E26 | 34.3 | 0.50 | 4.3 | 71 | 1.9 | 30 | 1.51 | 3.0 | 70 | 25.8 | 1.5 | 84 |
| E27 | 35.7 | 0.50 | 7.5 | 74 | 1.9 | 30 | 1.57 | 1.5 | 35 | 22.5 | 0.7 | 80 |

| | | | | | | | | | | | |
|---|---|---|---|---|---|---|---|---|---|---|---|
| Range - | Upper | 35.7 | 0.7 | 7.5 | 77 | 5.7 | 30 | 1.7 | 3.0 | 80 | 25.8 |
| examples | range | | | | | | | | | | |
| | Lower | 23.5 | 0.5 | 4.3 | 64 | 1.9 | 30 | 1.4 | 1.5 | 35 | 22.5 |
| | range | | | | | | | | | | |

| | | | | | | | | | | | | |
|---|---|---|---|---|---|---|---|---|---|---|---|---|
| C41 | 25.7 | 0.67 | 5.7 | 70 | 11.4 | 60 | 1.51 | 3.0 | 70 | 25.8 | 7.4 | 73 |
| C42 | 27.2 | 0.67 | 5.7 | 74 | 11.4 | 60 | 1.62 | 3.0 | 75 | 25.8 | 4.8 | 76 |
| C43 | 28.3 | 0.67 | 5.7 | 77 | 11.4 | 60 | 1.73 | 3.0 | 80 | 25.8 | 4.4 | 77 |
| C44 | 15.8 | 1.00 | 8.6 | 63 | 1.9 | 30 | 1.37 | 3.0 | 63 | 25.8 | 4.5 | 78 |
| C45 | 17.4 | 1.00 | 8.6 | 69 | 1.9 | 30 | 1.51 | 3.0 | 70 | 25.8 | 5 | 79 |
| C46 | 18.4 | 1.00 | 8.6 | 73 | 1.9 | 30 | 1.62 | 3.0 | 75 | 25.8 | 3.5 | 82 |
| C47 | 19.1 | 1.00 | 8.6 | 76 | 1.9 | 30 | 1.73 | 3.0 | 80 | 25.8 | 3.3 | 82 |
| C48 | 26.5 | 0.50 | 4.3 | 56 | 1.9 | 30 | 1.22 | 3.0 | 56 | 25.8 | 4.0 | 77 |
| C49 | 36.2 | 0.50 | 4.3 | 75 | 1.9 | 30 | 1.62 | 3.0 | 75 | 25.8 | 2.1 | 83 |
| C50 | 37.7 | 0.50 | 4.3 | 78 | 1.9 | 30 | 1.73 | 3.0 | 80 | 25.8 | 2.1 | 83 |
| C51 | 18.4 | 1.00 | 8.6 | 73 | 5.7 | 30 | 1.62 | 3.0 | 75 | 25.8 | 8.3 | 72 |
| C52 | 19.1 | 1.00 | 8.6 | 76 | 5.7 | 30 | 1.73 | 3.0 | 80 | 25.8 | 6.5 | 75 |
| C53 | 26.6 | 0.50 | 4.3 | 56 | 5.7 | 30 | 1.01 | 1.5 | 26 | 12.9 | 7.7 | 73 |
| C54 | 31.2 | 0.50 | 4.3 | 65 | 5.7 | 30 | 1.22 | 1.5 | 30 | 12.9 | 6.1 | 75 |
| C55 | 26.6 | 0.67 | 5.7 | 72 | 5.7 | 30 | 1.01 | 1.5 | 26 | 12.9 | 7.3 | 75 |
| C56 | 31.3 | 0.67 | 5.7 | 85 | 5.7 | 30 | 1.22 | 1.5 | 30 | 12.9 | 4.1 | 78 |
| C57 | 34.3 | 0.67 | 5.7 | 93 | 5.7 | 30 | 1.40 | 1.5 | 32 | 12.9 | 3.7 | 78 |
| C58 | 20.0 | 1.00 | 8.6 | 79 | 5.7 | 30 | 1.01 | 1.5 | 26 | 12.9 | 5.4 | 76 |
| C59 | 23.5 | 1.00 | 8.6 | 92 | 5.7 | 30 | 1.22 | 1.5 | 30 | 12.9 | 6.1 | 75 |
| C60 | 26.7 | 0.67 | 5.7 | 72 | 5.7 | 30 | 1.01 | 1.5 | 26 | 12.9 | 7.9 | 73 |
| C61 | 37.1 | 0.50 | 7.5 | 77 | 1.9 | 30 | 1.73 | 1.5 | 37 | 22.5 | 2.7 | 78 |

| | | | | | | | | | | | |
|---|---|---|---|---|---|---|---|---|---|---|---|
| Range - | Upper | 37.7 | 1.0 | 8.6 | 93 | 11.4 | 60 | 1.7 | 3.0 | 80 | 25.8 |
| examples | range | | | | | | | | | | |
| | Lower | 15.8 | 0.5 | 4.3 | 56 | 1.9 | 30 | 1.0 | 1.5 | 26 | 12.9 |
| | range | | | | | | | | | | |

Table 11 shows that, for each process variable, the range associated with the achievement of D≦2% and S≧80% for E21 through E27, after heating to 170° C. for 1 hour and subsequent heating to 190° C. for 1 hour, was contained within the respective range for C41 through C61. Thus Table 11 confirms the findings of Tables 1 through 10 that the achievement of D≦2% and S≧80% did NOT depend on a single variable, but on combinations of all ten variables measured in these tables.

### Tables 12 to 21

Tables 12 to 20 below depicts the variation in one variable versus the achieved D or S, after air treatment at 170° C. for one hour, when the HMDSO overcoat deposition was executed with a 13.56 MHz power generator and at a fixed pressure. Table 21 depicts the variation in all measured variables versus the achieved D or S using the same MHz power generator, after heating to 170° C. for one hour and a subsequent heating to 190° C. for one hour. Because the pressure at which the HMDSO overcoat deposition step occurred was held constant in Tables 12-21; nine, not ten, process variables were evaluated.

TABLE 12
Table 12. Reflectance performance after heating to 170° C. for 1 hour using
process conditions comprising similar Al target power density for:
E28; C62 and C63, similar high Al target power density; and
E29; C64 and C65, similar low Al target power density.

| | | High Target | | | Low Target | | |
|---|---|---|---|---|---|---|---|
| | | Power Density | | | Power Density | | |
| | | | High D | Low S | | High D | Low S |
| | | E28 | C62 | C63 | E29 | C64 | C65 |
| Al Process | Power density (W/cm²) | 37.1 | 36.9 | 36.9 | 9.6 | 9.6 | 9.6 |
| | Deposition time (min) | 0.50 | 0.50 | 0.50 | 1.00 | 1.50 | 1.00 |
| | Number of Passes | 2.0 | 12.0 | 12.0 | 8.6 | 12.9 | 24.0 |
| | Al Thickness (nm) | 77 | 77 | 77 | 39 | 56 | 39 |
| HMDSO | Residence time (s) | 5.7 | 5.7 | 5.7 | 1.9 | 1.9 | 1.9 |
| Process | Power density (W/cm²) | 1.73 | 1.73 | 1.73 | 1.02 | 1.02 | 1.02 |
| (13.56 MHz) | Deposition time (min) | 1.50 | 1.50 | 1.50 | 3.00 | 1.50 | 1.50 |
| | HMDSO Thickness (nm) | 157 | 157 | 157 | 114 | 70 | 70 |
| | Number of Passes | 6.0 | 36 | 36.0 | 25.8 | 12.9 | 36.0 |
| 170° C./1 hr | D (%) | 1.4 | 6.1 | 6.1 | 1.1 | 5.3 | 3.4 |
| Performance | S (%) | 84 | 79 | 79 | 84 | 62 | 62 |

Table 12 shows that the achievement of D≦2% and S≧80% after heating to 170° C. for 1 hour did NOT solely depend on the Al target power density.

TABLE 13
Table 13. Reflectance performance after heating to 170° C. for 1 hour using
process conditions comprising similar Al deposition time for:
E30; C66 and C67, similar long Al deposition time; and
E31; C68 and C69, similar short Al deposition time.

| | | Long Al | | | Short Al | | |
|---|---|---|---|---|---|---|---|
| | | Deposition Time | | | Deposition Time | | |
| | | | High D | Low S | | High D | Low S |
| | | E30 | C66 | C67 | E31 | C68 | C69 |
| Al Process | Power density (W/cm²) | 19.3 | 13.4 | 9.6 | 25.8 | 30.2 | 18.4 |
| | Deposition time (min) | 1.50 | 1.50 | 1.50 | 0.50 | 0.50 | 0.50 |
| | Number of Passes | 12.9 | 12.9 | 12.9 | 2.0 | 2.0 | 12.0 |
| | Al Thickness (nm) | 110 | 77 | 56 | 54 | 63 | 39 |
| HMDSO | Residence time (s) | 1.9 | 1.9 | 1.9 | 5.7 | 1.9 | 5.7 |
| Process | Power density (W/cm²) | 1.73 | 1.22 | 1.02 | 1.22 | 1.37 | 1.02 |
| (13.56 MHz) | Deposition time (min) | 1.50 | 1.50 | 1.50 | 1.50 | 1.50 | 1.50 |
| | HMDSO Thickness (nm) | 157 | 96 | 70 | 96 | 115 | 70 |
| | Number of Passes | 12.9 | 13.0 | 12.9 | 6.0 | 6.0 | 36.0 |
| 170° C./1 hr | D (%) | 1.6 | 5.8 | 5.3 | 1.1 | 4.6 | 2.5 |
| Performance | S (%) | 85 | 71 | 62 | 81 | 77 | 64 |

Table 13 shows that the achievement of D≦2% and S≧80% after heating to 170° C. for 1 hour did NOT solely depend on the Al deposition time.

TABLE 14
Table 14. Reflectance performance after heating to 170° C. for 1 hour using process
conditions comprising a similar number of passes during the Al deposition step for:
E32; C70 and C71, similar large number of passes; and E33; and C72 and C73,
similar small number of passes.

| | | Large Al | | | Small Al | | |
|---|---|---|---|---|---|---|---|
| | | Number of Passes | | | Number of Passes | | |
| | | | High D | Low S | | High D | Low S |
| | | E32 | C70 | C71 | E33 | C72 | C73 |
| Al Process | Power density (W/cm²) | 13.3 | 19.2 | 9.6 | 30.5 | 36.7 | 36.7 |
| | Deposition time (min) | 1.00 | 1.00 | 1.00 | 0.50 | 0.50 | 0.50 |
| | Number of Passes | 24.0 | 24.0 | 24.0 | 2.0 | 2.0 | 2.0 |
| | Al Thickness (nm) | 53 | 76 | 39 | 64 | 76 | 76 |
| HMDSO | Residence time (s) | 5.7 | 1.9 | 1.9 | 5.7 | 1.9 | 1.9 |
| Process | Power density (W/cm²) | 1.22 | 1.73 | 1.02 | 1.37 | 1.73 | 1.73 |
| (13.56 MHz) | Deposition time (min) | 1.50 | 1.50 | 1.50 | 1.50 | 1.50 | 1.50 |
| | HMDSO Thickness (nm) | 96 | 157 | 70 | 115 | 157 | 157 |
| | Number of Passes | 36.0 | 36 | 36.0 | 6.0 | 6.0 | 6.0 |
| 170° C./1 hr | D (%) | 1.9 | 6.4 | 3.4 | 1.3 | 9.3 | 9.3 |
| Performance | S (%) | 81 | 78 | 62 | 83 | 73 | 73 |

Table 14 shows that the achievement of D≦2% and S≧80% after air treatment at 170° C. for 1 hour did NOT solely depend on the number of passes during the Al deposition step.

TABLE 15
Table 15. Reflectance performance after heating to 170° C. for 1 hour using h process
conditions comprising a similar Al thickness for:
E34; C74 and C75, similar large Al thickness; and
E36; C76 and C77, similar small Al thickness.

| | | Large Al Thickness | | | Small Al Thickness | | |
|---|---|---|---|---|---|---|---|
| | | | High D | Low S | | High D | Low S |
| | | E34 | C74 | C75 | E35 | C76 | C77 |
| Al Process | Power density (W/cm²) | 19.3 | 27.4 | 27.4 | 9.6 | 9.6 | 9.6 |
| | Deposition time (min) | 1.50 | 1.00 | 1.00 | 1.00 | 1.00 | 1.00 |
| | Number of Passes | 12.9 | 4.0 | 4.0 | 8.6 | 8.6 | 24.0 |
| | Al Thickness (nm) | 110 | 107 | 107 | 39 | 39 | 39 |
| HMDSO | Residence time (s) | 1.9 | 5.7 | 5.7 | 1.9 | 1.9 | 1.9 |
| Process | Power density (W/cm²) | 1.73 | 1.62 | 1.62 | 1.02 | 1.02 | 1.02 |
| (13.56 MHz) | Deposition time (min) | 1.50 | 0.42 | 0.42 | 3.00 | 1.50 | 1.50 |
| | HMDSO Thickness (nm) | 157 | 59 | 59 | 114 | 70 | 70 |
| | Number of Passes | 12.9 | 2 | 1.7 | 25.8 | 12.9 | 36.0 |
| 170° C./1 hr | D (%) | 1.6 | 14.8 | 14.8 | 1.1 | 4.1 | 3.4 |
| Performance | S (%) | 85 | 66 | 66 | 84 | 66 | 62 |

Table 15 shows that the achievement of D≦2% and S≧80% after heating to 170° C. for 1 hour did NOT solely depend on the thickness of the deposited aluminum.

TABLE 16
Table 16. Reflectance performance after heating to 170° C. for 1 hour using process
conditions comprising a similar residence time in the HMDSO overcoat deposition step for:
E36; C78 and C79, similar long residence time; and E37; C80 and C81, similar short
residence time.

| | | High Target | | | | | |
|---|---|---|---|---|---|---|---|
| | | Power Density | | | Low Target Power Density | | |
| | | | High D | Low S | | High D | Low S |
| | | E36 | C78 | C79 | E37 | C80 | C81 |
| Al Process | Power density (W/cm²) | 28.5 | 27.4 | 28.5 | 9.6 | 18.5 | 9.6 |
| | Deposition time (min) | 0.67 | 1.00 | 1.00 | 1.00 | 0.50 | 1.00 |
| | Number of Passes | 2.7 | 4.0 | 4.0 | 8.6 | 4.3 | 24.0 |
| | Al Thickness (nm) | 77 | 107 | 111 | 39 | 39 | 39 |
| HMDSO | Residence time (s) | 5.7 | 5.7 | 5.7 | 1.9 | 1.9 | 1.9 |
| Process | Power density (W/cm²) | 1.73 | 1.62 | 1.73 | 1.02 | 1.02 | 1.02 |
| (13.56 MHz) | Deposition time (min) | 1.50 | 0.42 | 0.42 | 3.00 | 1.50 | 1.50 |
| | HMDSO Thickness (nm) | 157 | 59 | 64 | 114 | 70 | 70 |
| | Number of Passes | 6.0 | 2 | 1.7 | 25.8 | 12.9 | 36.0 |
| 170° C./1 hr | D (%) | 1.2 | 14.8 | 14.5 | 1.1 | 7.1 | 3.4 |
| Performance | S (%) | 85 | 66 | 66 | 84 | 68 | 62 |

Table 16 shows that the achievement of D≦2% and S≧80% after heating to 170° C. for 1 hour did NOT solely depend on the residence time during the HMDSO overcoat deposition step.

TABLE 17
Table 17. Reflectance performance after heating to 170° C. for 1 hour using process
conditions comprising a similar electrode power density in the HMDSO overcoat
deposition step for:
E38; C82 and C83, similar high electrode power density; and
E39; C84 and C85, similar low electrode power density.

| | | High Power Density | | | Low Power Density | | |
|---|---|---|---|---|---|---|---|
| | | | High D | Low S | | High D | Low S |
| | | E38 | C82 | C83 | E39 | C84 | C85 |
| Al Process | Power density (W/cm²) | 28.5 | 28.5 | 28.5 | 9.6 | 14.2 | 18.4 |
| | Deposition time (min) | 0.67 | 1 | 1 | 1 | 1 | 0.5 |
| | Number of Passes | 2.7 | 4 | 4 | 8.6 | 4 | 12 |
| | Al Thickness (nm) | 77 | 111 | 111 | 39 | 57 | 39 |
| HMDSO | Residence time (s) | 5.7 | 5.7 | 5.7 | 1.9 | 5.7 | 5.7 |
| Process | Power density (W/cm²) | 1.73 | 1.73 | 1.73 | 1.02 | 1.02 | 1.02 |
| (13.56 MHz) | Deposition time (min) | 1.5 | 0.42 | 0.42 | 3 | 0.42 | 1.5 |
| | HMDSO Thickness (nm) | 157 | 64 | 64 | 114 | 29 | 70 |
| | Number of Passes | 6 | 1.7 | 1.7 | 25.8 | 1.7 | 36 |
| 170° C./1 hr | D (%) | 1.2 | 14.5 | 14.5 | 1.1 | 7.8 | 2.5 |
| Performance | S (%) | 85 | 66 | 66 | 84 | 76 | 64 |

Table 17 shows that the achievement of D≦2% and S≧80% after heating to 170° C. for 1 hour did NOT solely depend on the electrode power density in the HMDSO process.

TABLE 18
Table 18. Reflectance performance after heating to 170° C. for 1 hour using process
conditions comprising a similar HMDSO overcoat deposition time for:
E40; C86 and C87, similar long deposition time;
E41; C88 and C89, similar short deposition time.

| | | Long HMDSO | | | Short HMDSO | | |
|---|---|---|---|---|---|---|---|
| | | Deposition Time | | | Deposition Time | | |
| | | | High D | Low S | | High D | Low S |
| | | E40 | C86 | C87 | E41 | C88 | C89 |
| Al Process | Power density (W/cm²) | 14.3 | 28.7 | 15.9 | 14.2 | 27.4 | 13.6 |
| | Deposition time (min) | 0.67 | 0.67 | 1.00 | 0.67 | 1.00 | 1.00 |
| | Number of Passes | 5.7 | 5.7 | 8.6 | 2.7 | 4.0 | 4.0 |
| | Al Thickness (nm) | 40 | 78 | 63 | 39 | 107 | 55 |
| HMDSO | Residence time (s) | 5.7 | 5.7 | 5.7 | 5.7 | 5.7 | 5.7 |
| Process | Power density (W/cm²) | 1.02 | 1.73 | 1.37 | 1.02 | 1.62 | 1.62 |
| (13.56 MHz) | Deposition time (min) | 3.00 | 3.00 | 3.00 | 0.42 | 0.42 | 0.42 |
| | HMDSO Thickness (nm) | 114 | 255 | 187 | 29 | 59 | 59 |
| | Number of Passes | 25.8 | 26 | 25.8 | 1.7 | 1.7 | 1.7 |
| 170° C./1 hr | D (%) | 1.4 | 3.1 | 2.4 | 1.3 | 14.8 | 14.8 |
| Performance | S (%) | 85 | 77 | 74 | 82 | 66 | 66 |

Table 18 shows that the achievement of D≦2% and S≧80% after heating to 170° C. for 1 hour did NOT solely depend on the HMDSO overcoat deposition time.

TABLE 19
Table 19. Reflectance performance after heating to 170° C. for 1 hour using process
conditions comprising a similar HMDSO overcoat thickness for:
E42; C90 and C91, similar large HMDSO overcoat thickness; and
E43; C92 and C93, similar small HMDSO overcoat.

| | | Large HMDSO | | | Small HMDSO | | |
|---|---|---|---|---|---|---|---|
| | | Thickness | | | Thickness | | |
| | | | High D | Low S | | High D | Low S |
| | | E42 | C90 | C91 | E43 | C92 | C93 |
| Al Process | Power density (W/cm²) | 17.4 | 35.7 | 27.6 | 19.9 | 19.8 | 11.4 |
| | Deposition time (min) | 1.00 | 0.50 | 0.67 | 0.67 | 1.00 | 1.00 |
| | Number of Passes | 8.6 | 4.3 | 5.7 | 2.7 | 4.0 | 4.0 |
| | Al Thickness (nm) | 69 | 74 | 75 | 54 | 78 | 46 |
| HMDSO | Residence time (s) | 1.9 | 1.9 | 5.7 | 5.7 | 5.7 | 5.7 |
| Process (13.56 MHz) | Power density (W/cm²) | 1.51 | 1.62 | 1.62 | 1.22 | 1.22 | 1.22 |
| | Deposition time (min) | 3.00 | 3.00 | 3.00 | 0.42 | 0.42 | 0.42 |
| | HMDSO Thickness (nm) | 213 | 235 | 235 | 39 | 39 | 39 |
| | Number of Passes | 25.8 | 26 | 25.8 | 1.7 | 1.7 | 1.7 |
| 170° C./1 hr | D (%) | 1.9 | 2.8 | 2.8 | 1.8 | 10.7 | 10.7 |
| Performance | S (%) | 80 | 80 | 77 | 80 | 72 | 72 |

Table 19 shows that the achievement of D≦2% and S≧80% after heating to 170° C. for 1 hour did NOT solely depend on the HMDSO overcoat thickness.

TABLE 20
Table 20. Reflectance performance after heating to 170° C. for 1 hour using process
conditions comprising a similar number of passes in the HMDSO overcoat deposition
step for:
E44; C94 C95, similar large number of passes;
E45; C96 and C97, similar small number of passes.

| | | Large Number of | | | Small Number of | | |
|---|---|---|---|---|---|---|---|
| | | Passes | | | Passes | | |
| | | | High D | Low S | | High D | Low S |
| | | E44 | C94 | C95 | E45 | C96 | C97 |
| Al Process | Power density (W/cm²) | 13.3 | 27.4 | 9.6 | 14.2 | 27.4 | 13.6 |
| | Deposition time (min) | 1.00 | 0.67 | 1.00 | 0.67 | 1.00 | 1.00 |
| | Number of Passes | 24.0 | 16.0 | 24.0 | 2.7 | 4.0 | 4.0 |
| | Al Thickness (nm) | 53 | 74 | 39 | 39 | 107 | 55 |
| HMDSO | Residence time (s) | 5.7 | 1.9 | 1.9 | 5.7 | 5.7 | 5.7 |
| Process | Power density (W/cm²) | 1.22 | 1.62 | 1.02 | 1.02 | 1.62 | 1.62 |
| (13.56 MHz) | Deposition time (min) | 1.50 | 1.50 | 1.50 | 0.42 | 0.42 | 0.42 |
| | HMDSO Thickness (nm) | 96 | 145 | 70 | 29 | 59 | 59 |
| | Number of Passes | 36.0 | 36.0 | 36.0 | 1.7 | 1.7 | 1.7 |
| 170° C./1 hr | D (%) | 1.9 | 7.2 | 3.4 | 1.3 | 14.8 | 14.8 |
| Performance | S (%) | 81 | 79 | 62 | 82 | 66 | 66 |

Table 20 shows that the achievement of D≦2% and S≧80% after heating to 170° C. for 1 hour did NOT solely depend on the number of passes in the HMDSO overcoat deposition step.

TABLE 21
Table 21. Reflectance performance after heating to170° C. for 1 hour and subsequent heating to 190° C. for 1 hour for:
E46 through E53 and C98 through C129, illustrating the range for each process variable.

| | Al Process | | | | HMDSO Process (13.56 MHz) | | | | | | 170° C./1 hr + | |
|---|---|---|---|---|---|---|---|---|---|---|---|---|
| | Power | | Number | Al | | | Power | | HMDSO | Number | 190° C./1 hr | |
| | density | Deposition | of | Thickness | Residence | Pressure | density | Deposition | Thickness | of | Performance | |
| | (W/cm²) | time (min) | Passes | (nm) | time (s) | (mTorr) | (W/cm²) | time (min) | (nm) | Passes | D (%) | S (%) |
| E46 | 9.6 | 1.00 | 8.6 | 39 | 1.9 | 30 | 1.02 | 3.0 | 114 | 25.8 | 1.1 | 84 |
| E47 | 15.9 | 1.00 | 4.0 | 63 | 5.7 | 30 | 1.37 | 1.5 | 115 | 6.0 | 1.9 | 81 |
| E48 | 17.5 | 1.00 | 4.0 | 70 | 5.7 | 30 | 1.51 | 1.5 | 131 | 6.0 | 1.3 | 84 |
| E49 | 18.6 | 1.00 | 4.0 | 74 | 5.7 | 30 | 1.62 | 1.5 | 145 | 6.0 | 1.5 | 84 |
| E50 | 19.3 | 1.00 | 4.0 | 77 | 5.7 | 30 | 1.73 | 1.5 | 157 | 6.0 | 1.4 | 84 |
| E51 | 23.5 | 0.67 | 2.7 | 64 | 1.9 | 30 | 1.37 | 1.5 | 115 | 6.0 | 1.3 | 82 |
| E52 | 25.9 | 0.67 | 2.7 | 70 | 1.9 | 30 | 1.51 | 1.5 | 131 | 6.0 | 1.7 | 82 |
| E53 | 13.3 | 1.00 | 4.0 | 53 | 5.7 | 30 | 1.22 | 1.5 | 96 | 6.0 | 1.8 | 81 |

| | | | | | | | | | | | |
|---|---|---|---|---|---|---|---|---|---|---|---|
| Range - | Upper | 25.9 | 1.00 | 8.6 | 77 | 5.7 | 30 | 1.7 | 3.0 | 157 | 25.8 |
| examples | range | | | | | | | | | | |
| | Lower | 9.6 | 0.67 | 2.7 | 39 | 1.9 | 30 | 1.0 | 1.5 | 96 | 6.0 |
| | range | | | | | | | | | | |

| | | | | | | | | | | | | |
|---|---|---|---|---|---|---|---|---|---|---|---|---|
| C98 | 23.5 | 0.67 | 5.7 | 64 | 5.7 | 30 | 1.37 | 1.5 | 115 | 12.9 | 8.7 | 74 |
| C99 | 30.7 | 0.50 | 4.3 | 64 | 1.9 | 30 | 1.37 | 1.5 | 115 | 12.9 | 10.5 | 72 |
| C100 | 33.8 | 0.50 | 4.3 | 70 | 1.9 | 30 | 1.51 | 1.5 | 131 | 12.9 | 7.6 | 77 |
| C101 | 35.9 | 0.50 | 4.3 | 75 | 1.9 | 30 | 1.62 | 1.5 | 145 | 12.9 | 6.3 | 79 |
| C102 | 13.4 | 1.00 | 8.6 | 54 | 5.7 | 30 | 1.22 | 1.5 | 96 | 12.9 | 1.6 | 79 |
| C103 | 15.9 | 1.00 | 8.6 | 63 | 5.7 | 30 | 1.37 | 1.5 | 115 | 12.9 | 8.4 | 76 |
| C104 | 17.5 | 1.00 | 8.6 | 69 | 5.7 | 30 | 1.51 | 1.5 | 131 | 12.9 | 10.0 | 76 |
| C105 | 18.6 | 1.00 | 8.6 | 73 | 5.7 | 30 | 1.62 | 1.5 | 145 | 12.9 | 7.5 | 78 |
| C106 | 19.3 | 1.00 | 8.6 | 76 | 5.7 | 30 | 1.73 | 1.5 | 157 | 12.9 | 5.9 | 80 |
| C107 | 19.8 | 0.67 | 5.7 | 54 | 5.7 | 30 | 1.22 | 1.5 | 96 | 12.9 | 12.3 | 68 |
| C108 | 23.4 | 0.67 | 5.7 | 64 | 5.7 | 30 | 1.37 | 1.5 | 115 | 12.9 | 7.7 | 77 |
| C109 | 35.6 | 0.50 | 4.3 | 74 | 1.9 | 30 | 1.61 | 1.5 | 145 | 12.9 | 3.8 | 82 |
| C110 | 14.3 | 0.67 | 5.7 | 40 | 5.7 | 30 | 1.02 | 3.0 | 114 | 25.8 | 7.1 | 78 |
| C111 | 25.9 | 0.50 | 4.3 | 54 | 5.7 | 30 | 1.22 | 3.0 | 156 | 25.8 | 7.0 | 77 |
| C112 | 17.4 | 1.00 | 8.6 | 69 | 1.9 | 30 | 1.51 | 3.0 | 213 | 25.8 | 4.4 | 76 |
| C113 | 25.9 | 0.67 | 5.7 | 70 | 1.9 | 30 | 1.51 | 3.0 | 213 | 25.8 | 4.0 | 77 |
| C114 | 35.6 | 0.50 | 4.3 | 74 | 5.7 | 30 | 1.62 | 1.5 | 145 | 12.9 | 3.5 | 80 |
| C115 | 23.7 | 0.67 | 5.7 | 65 | 1.9 | 30 | 1.37 | 1.5 | 115 | 12.9 | 18.5 | 66 |
| C116 | 23.4 | 1.00 | 8.6 | 92 | 5.7 | 30 | 1.37 | 1.5 | 115 | 12.9 | 6.9 | 80 |
| C117 | 18.6 | 1.50 | 12.9 | 106 | 1.9 | 30 | 1.62 | 1.5 | 145 | 12.9 | 18.7 | 67 |
| C118 | 19.3 | 1.50 | 12.9 | 110 | 1.9 | 30 | 1.73 | 1.5 | 157 | 12.9 | 10.8 | 75 |
| C119 | 23.5 | 0.67 | 2.7 | 64 | 5.7 | 30 | 1.37 | 1.5 | 115 | 6.0 | 2.7 | 80 |
| C120 | 25.9 | 0.67 | 2.7 | 70 | 5.7 | 30 | 1.51 | 1.5 | 131 | 6.0 | 4.5 | 80 |
| C121 | 27.4 | 0.67 | 2.7 | 74 | 5.7 | 30 | 1.62 | 1.5 | 145 | 6.0 | 7.2 | 78 |
| C122 | 28.5 | 0.67 | 2.7 | 77 | 5.7 | 30 | 1.73 | 1.5 | 157 | 6.0 | 7.1 | 78 |
| C123 | 25.8 | 0.50 | 2.0 | 54 | 5.7 | 30 | 1.22 | 1.5 | 96 | 6.0 | 2.9 | 79 |
| C124 | 30.5 | 0.50 | 2.0 | 64 | 5.7 | 30 | 1.37 | 1.5 | 115 | 6.0 | 2.6 | 81 |
| C125 | 33.6 | 0.50 | 2.0 | 70 | 5.7 | 30 | 1.51 | 1.5 | 131 | 6.0 | 2.6 | 82 |
| C126 | 35.6 | 0.50 | 2.0 | 74 | 5.7 | 30 | 1.62 | 1.5 | 145 | 6.0 | 2.6 | 82 |
| C127 | 37.1 | 0.50 | 2.0 | 77 | 5.7 | 30 | 1.73 | 1.5 | 157 | 6.0 | 2.3 | 83 |
| C128 | 14.2 | 0.67 | 2.7 | 39 | 5.7 | 30 | 1.02 | 0.4 | 29 | 1.7 | 5.1 | 77 |
| C129 | 19.9 | 0.67 | 2.7 | 54 | 5.7 | 30 | 1.22 | 0.4 | 39 | 1.7 | 3.8 | 78 |

| | | | | | | | | | | | |
|---|---|---|---|---|---|---|---|---|---|---|---|
| Range - | Upper | 37.1 | 1.5 | 12.9 | 110 | 5.7 | 30 | 1.7 | 3.0 | 213 | 25.8 |
| examples | range | | | | | | | | | | |
| | Lower | 13.4 | 0.5 | 2.0 | 39 | 1.9 | 30 | 1.0 | 0.4 | 29 | 1.7 |
| | range | | | | | | | | | | |

Table 21 shows, that for each process variable, the range associated with the achievement of D≦2% and S≧80%, after heating to 170° C. for 1 hour and subsequent heating to 190° C. for 1 hour, for E46 through E53 was contained within the respective range for C98 through C151. Thus, Table 21 confirms the findings of Tables 12 through 20 that the achievement of D≦2% and S≧80% did NOT depend on a single variable, but on combinations of all variables measured in these tables.

Model of Relationships among Process Variables

Having demonstrated that achievement of D≦2% and S≧80% did NOT depend on a single variable, a more complex analysis of the data was undertaken to understand how the process variables combined with each other to determine the achievement of D≦2% and S≧80%. In addition, the model included the conditions of the HMDSO discharge completed in the previous run to account for conditioning effects on the internal surfaces of the chamber and the surfaces of process components within. To that end, quadratic Taylor expansions were used to model both D and S, after heating to 170° C. for 1 hour, as a function of process variables.

### Modeling Using a 40 kHz Power Generator for the Overcoat Deposition Step

When the HMDSO overcoat deposition step used a 40 kHz power generator, the process variables of the model included:

(a) chamber conditioning prior to the Al process:

HMDSO process base pressure (X₁), i.e., chamber pressure when the pump operated at full conductance and the HMDSO discharge was not ignited;

HMDSO process pressure (X₂), i.e., pump operating at a controlled throttled condition to maintain a desired pressure for the HMDSO discharge; and

HMDSO process energy (X₃), i.e., the product of discharge power and discharge duration.

(b) Al deposition step:

power density (X₄);

layer thickness (X₅); and

number of passes (X₆).

(c) HMDSO overcoat deposition step:

HMDSO process base pressure (X₇), i.e., chamber pressure when the pump operated at full conductance and the HMDSO discharge was not ignited;

HMDSO process pressure (X₈), i.e., pump operating at a controlled throttled condition to maintain a desired pressure for the HMDSO discharge;

layer thickness (X₉); and

number of passes (X₁₀).

Under this formalism, the following relationships applied:

D[Diffuse Reflectance]=f(N₁,N₂, . . . ,N₁₀)=ΣdᵢⱼNᵢNⱼ, with 0≦i≦10 and j≧i (1)

S[Specular Reflectance]=g(N₁,N₂, . . . ,N₁₀)=ΣsᵢⱼNᵢNⱼ, with 0≦i≦10 and j≧i (2)

with Nᵢ being normalized process variables determined by the following linear transformation:

N₀=1 (3)

Nᵢ=(Xᵢ−a)/b, for 1≦i≦10 (4)

where,
a=(X_{i,max}+X_{i,min})/2 and b=(X_{i,max}−X_{i,min})/2, with X_{i,max} and X_{i,min} being the maximum algebraic level and minimum algebraic level, respectively, of Xᵢ within the 10-dimensional process space.

Taylor expansions (1) and (2) contained sixty six terms (one constant, ten linear terms, ten quadratic terms and forty five cross terms) whose constants were optimized to minimize the error between predicted and actual performance. The error, E, was calculated as follows:

E=Σ(Y^{(k)}_{predicted}−Y^{(k)}_{actual})²/ΣY^{(k)}_{actual}² (5)

where,
Y^{(k)} was the performance (D or S) of each evaluated k^{th} process state, and the summations comprised all evaluated process states. The goodness of fit (“GF”) for a model, GF, was calculated as follows:

GF=1−E (6)

GF relates to the predictability of the model. Table 22 below details the sixty-six optimized constants for the D and S models.

TABLE 22
Table 22. Optimized quadratic model constants for D (diffuse reflectance) and S (specular reflectance) after air treatment at
170° C. for 1 hour.
The HMDSO overcoat deposition step using was executed with a 40 kHz power generator.

| | | | N₀ | N₁ | N₂ | N₃ | N₄ | N₅ | N₆ | N₇ | N₈ | N₉ | N₁₀ |
|---|---|---|---|---|---|---|---|---|---|---|---|---|---|
| | DIFFUSE dᵢⱼ | | | | | | | | | | | | |
| | | N₀ | −0.9 | −19.2 | −6.0 | −7.1 | 1.6 | 0.5 | 2.0 | −15.1 | −21.8 | −1.1 | −4.4 |
| Chamber | Process Base Pressure | N₁ | | −0.5 | −7.0 | 0.8 | 0.2 | 0.3 | 0.4 | 0.0 | −12.5 | −0.6 | −0.6 |
| conditioning | Process Pressure | N₂ | | | −10.0 | −3.9 | 3.1 | 2.9 | 0.2 | −6.4 | −4.6 | −3.1 | −2.4 |
| | Process Energy (W * min) | N₃ | | | | 0.5 | −1.2 | 0.2 | −2.0 | −0.6 | −2.9 | 0.0 | 2.1 |
| Al Process | Power Density (W/cm²) | N₄ | | | | | 0.5 | −1.5 | 0.8 | −0.3 | −1.9 | 3.6 | −1.0 |
| | Layer Thickness | N₅ | | | | | | 0.5 | −1.2 | 0.2 | −3.3 | −0.2 | 0.7 |
| | Number of Passes | N₆ | | | | | | | 0.3 | −0.9 | 1.4 | 3.6 | 1.1 |
| HMDSO | Process Base Pressure | N₇ | | | | | | | | 0.2 | −8.1 | −0.4 | 1.1 |
| Process | Process Pressure | N₈ | | | | | | | | | −9.5 | 2.2 | −3.3 |
| (40 kHz) | Layer Thickness | N₉ | | | | | | | | | | −0.3 | −0.8 |
| | Number of Passes | N₁₀ | | | | | | | | | | | −2.8 |
| | SPECULAR Sᵢⱼ | | | | | | | | | | | | |
| | | N₀ | 63.7 | −22.1 | −10.3 | −12.7 | −9.9 | 4.2 | −16.9 | −17.4 | −26.5 | −8.0 | 0.8 |
| Chamber | Process Base Pressure | N₁ | | −0.3 | −7.5 | −3.1 | −1.0 | −0.1 | −1.7 | 0.9 | −14.6 | 1.1 | 1.3 |
| conditioning | Process Pressure | N₂ | | | −11.1 | −3.8 | 3.2 | −1.0 | 0.1 | −7.0 | −5.0 | 0.0 | −8.1 |
| | Process Energy (W * min) | N₃ | | | | 7.3 | 2.6 | 3.1 | 1.8 | 1.3 | −1.5 | −4.9 | −7.8 |
| Al Process | Power Density (W/cm²) | N₄ | | | | | 0.7 | 5.1 | −3.7 | 1.5 | −2.3 | −14.2 | 2.9 |
| | Layer Thickness | N₅ | | | | | | −4.2 | 8.2 | −1.4 | −1.3 | 7.8 | −8.1 |
| | Number of Passes | N₆ | | | | | | | −1.4 | 1.6 | 1.4 | −24.6 | 11.4 |
| HMDSO | Process Base Pressure | N₇ | | | | | | | | −1.1 | −10.0 | 1.4 | −0.5 |
| Process | Process Pressure | N₈ | | | | | | | | | −10.7 | −0.5 | −7.2 |
| (40 kHz) | Layer Thickness | N₉ | | | | | | | | | | −6.4 | 26.3 |
| | Number of Passes | N₁₀ | | | | | | | | | | | −8.6 |

The degree of non-linearity in the quadratic Taylor model for Diffuse Reflectance, identified as NL_{D}, is given by the contributions of the squared and the cross terms and was calculated as according to the following:

For each normalized process variable Nᵢ, the contribution of the linear terms relative to all terms influencing Nᵢ, is given by

L_{D,i}=Σ|d₀ᵢ|/Σ|dₖ₁|, where 1≦k≦10 and 1≧k. (7)

And the non-linearity of the full model is given by

NL_{D}=1−ΣL_{D,i} with 1≦i≦10 (8)

NL_{D}, that is, the degree of non-linearity in the quadratic Taylor model for Diffuse Reflectance, was calculated to be 78%, indicating that 78% of the modeled diffuse reflectance was accounted for by the contributions of non-linear terms.

Attained goodness of fit, GF, which relates to the predictability of the quadratic Taylor model, was 0.95 for the Diffuse Reflectance model, indicating that it attained a predictability of 95%.

Similarly, the degree of non-linearity in the quadratic Taylor model for Specular Reflectance, identified as NL_{S}, was calculated to be 78%, indicating that 78% of the variation in the specular reflectance was accounted for by the contributions of non-linear terms.

Attained goodness of fit, GF, was 1.00 in the quadratic Taylor model for the Specular Reflectance model, indicating that it attained a predictability of 100%.

### Modeling Using a 13.56 MHz Power Generator for the Overcoat Deposition Step

When the HMDSO overcoat deposition step was executed with a 13.56 MHz power generator, a fixed process pressure was used for all substeps in the HMDSO deposition step. Therefore, in this case the process variables of the model included:

(a) chamber conditioning prior to the Al process:

HMDSO base pressure (X₁); and

HMDSO process energy (X₂).

(b) Al process:

power density (X₃);

layer thickness (X₄); and

number of passes (X₅).

(c) HMDSO process:

HMDSO process base pressure (X₆);

layer thickness (X₇); and

number of passes (X₈).

Under this formalism, similar relationships applied as presented above. Table 23 below details the forty five optimized constants for the D and S models.

Under this formalism, the following relationships applied:

D[Diffuse Reflectance]=f(N₁,N₂, . . . ,N₁₀)=ΣdᵢⱼNᵢNⱼ, with 0≦i≦8 and j≧i (9)

S[Specular Reflectance]=g(N₁,N₂, . . . ,N₁₀)=ΣsᵢⱼNᵢNⱼ, with 0≦i≦18 and j≧i (10)

with Nᵢ being normalized process variables determined by the following linear transformation:

N₀=1 (3)

Nᵢ=(Xᵢ−a)/b, for 1≦i≦8 (11)

whereby a=(X_{i,max}+X_{i,min})/2 and b=(X_{i,max}−X_{i,min})/2, with X_{i,max} and X_{i,min} being the maximum algebraic level and minimum algebraic level, respectively, of Xᵢ within the 8-dimensional process space.

Taylor expansions (1) and (2) contained forty five terms (one constant, eight linear terms, eight quadratic terms and twenty eight cross terms) whose constants were optimized to minimize the error between predicted and actual performance. The error, E, was calculated as follows:

E=ΣY^{(k)}_{predicted}−Y^{(k)}_{actual})²ΣY^{(k)}_{actual}² (5)

where Y^{(k)} was the performance (D or S) of each evaluated k^{th} process state, and the summations comprised all evaluated process states. The goodness of fit for a model, GF, was calculated as follows:

GF=1−E (6)

GF relates to the predictability of the model. Table 23 below details the forty five optimized constants for the D and S models.

The degree of non-linearity in the quadratic Taylor model for Diffuse Reflectance was 87%; thus, 87% of the variation in diffuse reflectance was accounted for by the contributions of non-linear terms. Attained goodness of fit, GF, was 0.94 indicating that it attained a predictability of 94%.

The degree of non-linearity in the quadratic Taylor model for Specular Reflectance was 86%, indicating 86% of the variation in specular reflectance was accounted for by contributions of non-linear terms. Attained goodness of fit, GF, was 100% indicating that it attained a predictability of 100%.

TABLE 23
Table 23. Optimized quadratic model constants for D (diffuse reflectance) and S (specular reflectance)
after heating to 170° C. for 1 hour.
The HMDSO overcoat deposition step was executed with a 13.56 MHz power generator.

| | | | N₀ | N₁ | N₂ | N₃ | N₄ | N₅ | N₆ | N₇ | N₈ |
|---|---|---|---|---|---|---|---|---|---|---|---|
| | DIFFUSE dᵢⱼ | | | | | | | | | | |
| | | N₀ | −0.7 | 0.4 | 0.4 | 1.9 | 2.4 | 0.1 | 0.8 | −3.7 | 1.4 |
| Chamber | Process Base Pressure | N₁ | | 2.9 | 0.2 | 0.2 | 0.9 | −0.6 | −0.3 | −1.8 | 1.2 |
| conditioning | Process Energy (W * min) | N₂ | | | −0.5 | −0.8 | 1.2 | −2.0 | 0.9 | −1.0 | 0.1 |
| Al Process | Power Density (W/cm²) | N₃ | | | | −0.8 | 1.1 | 2.4 | 0.6 | 0.9 | −1.6 |
| | Layer Thickness | N₄ | | | | | −0.9 | −0.1 | −0.2 | 1.4 | 1.9 |
| | Number of Passes | N₅ | | | | | | 0.8 | 1.3 | −2.0 | 0.1 |
| HMDSO Process | Process Base Pressure | N₆ | | | | | | | 3.5 | −0.1 | −2.2 |
| (13.56 MHz) | Layer Thickness | N₇ | | | | | | | | 0.3 | −1.1 |
| | Number of Passes | N₈ | | | | | | | | | −0.7 |
| | SPECULAR Sᵢⱼ | | | | | | | | | | |
| | | N₀ | 83.8 | −4.6 | 6.1 | 23.2 | −9.6 | 25.4 | 4.8 | 5.8 | −22.0 |
| Chamber | Process Base Pressure | N₁ | | 7.8 | −4.4 | −5.3 | 1.5 | −7.3 | −1.9 | 1.4 | 9.4 |
| conditioning | Process Energy (W * min) | N₂ | | | −4.5 | −6.6 | 8.5 | −6.8 | 2.3 | −8.4 | 8.1 |
| Al Process | Power Density (W/cm²) | N₃ | | | | −2.7 | −14.8 | 33.2 | 3.7 | 19.0 | −5.6 |
| | Layer Thickness | N₄ | | | | | 6.4 | −24.0 | −3.3 | −13.8 | 3.3 |
| | Number of Passes | N₅ | | | | | | 13.0 | 8.9 | 23.5 | −16.0 |
| HMDSO Process | Process Base Pressure | N₆ | | | | | | | 8.4 | 3.6 | −8.4 |
| (13.56 MHz) | Layer Thickness | N₇ | | | | | | | | 7.9 | −15.5 |
| | Number of Passes | N₈ | | | | | | | | | 3.3 |

The Influence Iᵢ of a normalized process variable Nᵢ, given by

Iᵢ=∂Y/∂Nᵢ=dₒᵢ+2dᵢᵢNᵢ+ΣdᵢⱼNⱼ (12)

with Y being D (diffuse reflectance) or S (specular reflectance) and i≠j enables the quantitative estimate of the relative influence of the various processes—chamber conditioning, Al step and HMDSO step—on the attained levels of diffuse and specular reflectances after heat aging.

The non-linear terms in (12) are dependent on the values of Nᵢ and Nⱼ within the process space implying that such terms will attain their maximum possible absolute values at the maximum and minimum levels for Nᵢ or Nⱼ, i.e., +1 and −1. Therefore, Iᵢ will lie between the following extreme algebraic levels.

I_{i,+}=dₒᵢ+(2|dᵢᵢ|+Σ|dᵢⱼ|) (13.1)

I_{i,-}=dₒᵢ−(2|dᵢᵢ|+Σ|dᵢⱼ|) (13.2)

The influence of the various steps, PI, when the HMDSO discharge was ignited with a 40 kHz power supply, are given by

PI_{conditioning,+}=average(I_{1,+},I_{2,+},I_{3,+}) (14.1)

PI_{Al,+}=average(I_{4,+},I_{5,+},I_{6,+}) (14.2)

PI_{HMDSO,+}=average(I_{7,+},I_{8,+},I_{9,+},I_{10,+}) (14.3)

The relative influence RI of a step, when operating under conditions that yield the most positive influence of each process variable, is given by the normalized level for that step, i.e.,

RI_{conditioning,+}=PI_{conditioning,+}/(PI_{conditioning,+}+PI_{Al,+}+PI_{HMDSO,+}) (15.1)

RI_{Al,+}=PI_{Al,+}/(PI_{conditioning,+}+PI_{Al,+}+PI_{HMDSO,+}) (15.2)

RI_{HMDSO,+}=PI_{HMDSO,+}/(PI_{conditioning,+}+PI_{Al,+}+PI_{HMDSO,+}) (15.3)

conversely,

RI_{conditioning,-}=PI_{conditioning,-}/(PI_{conditioning,-}+PI_{Al,-}+PI_{HMDSO,-}) (16.1)

RI_{Al,-}=PI_{Al,-}/(PI_{conditioning,-}+PI_{Al,-}+PI_{HMDSO,-}) (16.2)

RI_{HMDSO,-}=PI_{HMDSO,-}/(PI_{conditioning,-}+PI_{Al,-}+PI_{HMDSO,-}) (16.3)

The overall relative process influence can be represented by the average between RI₊ and RI₋.

TABLE 24
Table 24. Relative influence of various steps, when the HMDSO discharge was ignited
with a 40 kHz power supply

| | | | I₋ | I₊ | PI₋ | PI₊ | RI₋ | RI₊ | RI_{average} |
|---|---|---|---|---|---|---|---|---|---|
| | DIFFUSE dᵢⱼ | | | | | | | | |
| Chamber | Process Base Pressure | N1 | −43 | 4 | −41 | 20 | 45 | 39 | 42 |
| conditioning | Process Pressure | N2 | −60 | 48 | | | | | |
| | Process Energy (W * min) | N3 | −22 | 8 | | | | | |
| Al Process | Power Density (W/cm²) | N4 | −13 | 16 | −11 | 14 | 13 | 28 | 20 |
| | Layer Thickness | N5 | −11 | 12 | | | | | |
| | Number of Passes | N6 | −10 | 14 | | | | | |
| HMDSO Process | Process Base Pressure | N7 | −33 | 3 | −38 | 17 | 42 | 34 | 38 |
| (40 kHz) | Process Pressure | N8 | −81 | 37 | | | | | |
| | Layer Thickness | N9 | −16 | 14 | | | | | |
| | Number of Passes | N10 | −23 | 14 | | | | | |
| | SPECULAR Sᵢⱼ | | | | | | | | |
| Chamber | Process Base Pressure | N1 | −54 | 10 | −60 | 30 | 31 | 24 | 27 |
| conditioning | Process Pressure | N2 | −68 | 48 | | | | | |
| | Process Energy (W * min) | N3 | −57 | 32 | | | | | |
| Al Process | Power Density (W/cm²) | N4 | −47 | 28 | −54 | 39 | 28 | 31 | 29 |
| | Layer Thickness | N5 | −40 | 49 | | | | | |
| | Number of Passes | N6 | −74 | 40 | | | | | |
| HMDSO Process | Process Base Pressure | N7 | −45 | 10 | −82 | 57 | 42 | 45 | 44 |
| (40 kHz) | Process Pressure | N8 | −92 | 39 | | | | | |
| | Layer Thickness | N9 | −102 | 86 | | | | | |
| | Number of Passes | N10 | −90 | 92 | | | | | |

Table 24 presents RI results for the two deposition steps, when the HMDSO discharge was ignited with a 40 kHz power supply. Therefore, the Al step had a relative influence smaller than 30%. This means that the overall process was heavily dominated by the HMDSO step, when using a 40 kHz power supply to ignite the HMDSO discharge.

TABLE 25
Table 25. Relative influence of various steps, when the HMDSO discharge was ignited with a
13.56 MHz power supply

| | | | I₋ | I₊ | PI₋ | PI₊ | RI₋ | RI₊ | RI_{average} |
|---|---|---|---|---|---|---|---|---|---|
| | DIFFUSE dᵢⱼ | | | | | | | | |
| Chamber | Process Base Pressure | N1 | −11 | 11 | −9 | 9 | 32 | 32 | 32 |
| conditioning | Process Energy (W * min) | N2 | −7 | 8 | | | | | |
| Al Process | Power Density (W/cm²) | N3 | −7 | 11 | −8 | 11 | 28 | 36 | 32 |
| | Layer Thickness | N4 | −6 | 11 | | | | | |
| | Number of Passes | N5 | −10 | 10 | | | | | |
| HMDSO Process | Process Base Pressure | N6 | −12 | 13 | −11 | 10 | 40 | 33 | 36 |
| (13.56 MHz) | Layer Thickness | N7 | −13 | 5 | | | | | |
| | Number of Passes | N8 | −8 | 11 | | | | | |
| | SPECULAR Sᵢⱼ | | | | | | | | |
| Chamber | Process Base Pressure | N1 | −51 | 42 | −50 | 51 | 22 | 21 | 22 |
| conditioning | Process Energy (W * min) | N2 | −48 | 60 | | | | | |
| Al Process | Power Density (W/cm²⁾ | N3 | −70 | 117 | −94 | 120 | 42 | 50 | 46 |
| | Layer Thickness | N4 | −91 | 72 | | | | | |
| | Number of Passes | N5 | −120 | 171 | | | | | |
| HMDSO Process | Process Base Pressure | N6 | −44 | 54 | −78 | 70 | 35 | 29 | 32 |
| (13.56 MHz) | Layer Thickness | N7 | −95.0 | 107 | | | | | |
| | Number of Passes | N8 | −95 | 51 | | | | | |

Table 25 presents similar results for a process that used a 13.56 MHz power supply to ignite the HMDSO discharge. In this case, the HMDSO step was also the dominant one as the Al step had a relative influence smaller than 47%.

What is claimed is:

1. A process,
comprising the following steps done sequentially:
(1) vapor depositing onto a surface of an article comprising a semi-crystalline polymer composition a coating comprising aluminum;
(2) vapor depositing onto the same surface of the article an overcoat comprising hexamethyl disiloxane; and
to result in an article that, when heated to a maximum temperature between 165° C. and 190° C. between one hour and 4 hours, has a surface coated with an aluminum coating of thickness less than 200 nm and with an overcoat comprising hexamethyl disiloxane of thickness less than 325 nm,
said surface being visibly line free and
having a diffuse reflectance equal to or less than 2%, as measured at 600 nm by a conventional reflectance method comprising ASTM C1650-07,
wherein:
step (1) occurs in a vapor deposition chamber in an atmosphere of sputtering gas, and is done by the following substeps:
(a) sputter vaporizing the surface of an aluminum target at a maximum target power density ranging between 40 W/cm² for a maximum duration of 2 minutes; and
(b) passing the article in front of the sputtered aluminum target surface for a maximum ranging between 2 and 25 passes; and
step (2) occurs in a vapor deposition chamber and is done by the following substeps:
(c) replacing the sputtering gas in the vapor deposition chamber with flowing hexamethyl disiloxane;
(d) flowing the hexamethyl disiloxane to achieve a residence time within the vapor deposition chamber ranging between 1 second and 20 seconds at a pressure ranging between 20 mTorr and 75 mTorr;
(e) sustaining a hexamethyl disiloxane discharge at a maximum power density ranging between 0.5 W/cm² and 3 W/cm² for a maximum duration ranging between 0.2 minutes and 3.3 minutes; and
(f) exposing the article to the hexamethyl disiloxane discharge for a maximum ranging between 1 and 40 times.

2. The process of claim 1, further comprising, before step 1, a step of pre-conditioning the interior of the vapor deposition chamber, whereby the interior of the vapor deposition chamber retains species derived from the most recent hexamethyl disiloxane discharge sustained in the chamber.

3. The process of claim 1, wherein the semi-crystalline polymer composition comprises a semi-crystalline polymer selected from the group consisting of polybutylene terephthalate, polyethylene terephthalate, or polytrimethylene terephthalate, and mixtures of these and further comprises 0 to 2 weight percent of at least one lubricant selected from the group consisting of long chain fatty acid polyol esters, salts of long chain fatty acids, hydrogenated castor oil, pentaerythritol tetramontanoate, dipentaerythritol hexastearate, sodium montanate, and mixtures of these.

4. The process of claim 1, wherein the semi-crystalline polymer composition comprises 0 to 2 weight percent carbon black and 0 to 15 weight percent mineral fillers selected from the group consisting of talc, barium sulfate, calcium carbonate, titanium dioxide, and mixtures of these.

5. The process of claim 1, wherein the sputtering gas is argon.

6. The process of claim 1, wherein the pressure of the atmosphere of step (1) ranges between 1.5 mTorr and 10 mTorr

7. The process of claim 1, wherein the thickness of the aluminum coating is not more than 170 nm.

8. The process of claim 1, wherein the pressure of step (2d) ranges between 20 mTorr and 40 mTorr.

9. The process of claim 1, wherein the maximum power density of step 2(e) ranges between 0.6 W/cm² and 2.5 W/cm².

10. The process of claim 1, wherein the thickness of the overcoat is not less than 20 nm.

11. The process of claim 1, wherein the surface of the article has a specular reflectance equal to or greater than 80%, as measured at 600 nm by a conventional reflectance method, comprising ASTM C1650-07.

12. The process of claim 2, wherein the pressure of step (2d) ranges between 20 mTorr and 40 mTorr.

13. The process of claim 12, wherein the maximum power density of step 2(e) ranges between 0.6 W/cm² and 2.5 W/cm².

14. The process of claim 3, wherein the pressure of step (2d) ranges between 20 mTorr and 40 mTorr.

15. The process of claim 3, wherein the pressure of step (2d) ranges between 20 mTorr and 40 mTorr and the maximum power density of step 2(e) ranges between 0.6 W/cm² and 2.5 W/cm².

16. An article prepared by the process of claim 2.

17. An article having a surface coated by a process comprising the following steps done sequentially:
(1) vapor depositing onto a surface of an article comprising a semi-crystalline polymer composition a coating comprising aluminum;
(2) vapor depositing onto the same surface of the article an overcoat comprising hexamethyl disiloxane;
such that the surface of the article, when the article has been heated to a maximum temperature between 165° C. and 190° C. for at least one hour and up to 24 hours:
is coated with an aluminum coating of thickness less than 300 nm and with an overcoat comprising hexamethyl disiloxane of thickness less than 300 nm;
is visibly line free, and
has a diffuse reflectance equal to or less than 2%, as measured at 600 nm by a conventional reflectance method comprising ASTM C1650-07,
step (1) occurs in a vapor deposition chamber in an atmosphere of sputtering gas, and
is done by the following substeps:
(a) sputter vaporizing the surface of an aluminum target at a maximum target power density ranging between 10 W/cm² and 40 W/cm² for a maximum duration of 2 minutes; and
(b) passing the article in front of the sputtered aluminum target surface for a maximum ranging between 2 and 25 passes; and
step (2) occurs in a vapor deposition chamber and is done by the following substeps:
(c) replacing the sputtering gas in the vapor deposition chamber with flowing hexamethyl disiloxane;
(d) flowing the hexamethyl disiloxane to achieve a residence time within the vapor deposition chamber ranging between 1 second and 20 seconds at a pressure ranging between 20 mTorr and 75 mTorr;
(e) sustaining a hexamethyl disiloxane discharge at a maximum power density ranging between 0.6 W/cm² and 3 W/cm² for a maximum duration ranging between 0.2 minutes and 3.3 minutes; and
(f) exposing the article to the hexamethyl disiloxane discharge for a maximum ranging between 1 and 40 times.

18. The article of claim 17 in the form of a vehicle bezel.

19. The article of claim 18, wherein the pressure of step (2d) ranges between 20 mTorr and 40 mTorr and the maximum power density of step 2(e) ranges between 0.6 W/cm² and 2.5 W/cm².

20. The article of claim of claim 19, the semi-crystalline polymer composition comprises a semi-crystalline polymer selected from the group consisting of polybutylene terephthalate, polyethylene terephthalate, or polytrimethylene terephthalate, and mixtures of these and further comprises 0 to 2 weight percent of at least one lubricant selected from the group consisting of long chain fatty acid polyol esters, salts of long chain fatty acids, hydrogenated castor oil, pentaerythritol tetramontanoate, dipentaerythritol hexastearate, sodium montanate, and mixtures of these.
